(19) United States
(12) Patent Application Publication
(10) Pub. No.: US 2026/0362701 A1
(43) Pub. Date: Nov. 12, 2026

(54) SEMICONDUCTOR DEVICE INCLUDING CAPACITOR STRUCTURE AND ELECTRONIC SYSTEM INCLUDING THE SAME

(71) Applicant: SAMSUNG ELECTRONICS CO., LTD., Suwon-si (KR)

(72) Inventors: Jonghyeon JEONG, Suwon-si (KR); Donghoon KWON, Suwon-si (KR)

(73) Assignee: SAMSUNG ELECTRONICS CO., LTD., Suwon-si (KR)

(21) Appl. No.: 19/436,450

(22) Filed: Dec. 30, 2025

(30) Foreign Application Priority Data
May 8, 2025 (KR) 10-2025-0060038

(51) Int. Cl. H10B 43/50; H10B 41/10; H10B 41/27; H10B 41/35; H10B 41/41; H10B 41/50; H10B 43/10; H10B 43/27; H10B 43/35; H10B 43/40

(52) U.S. Cl. CPC H10B 43/50; H10B 41/10; H10B 41/27; H10B 41/35; H10B 41/41; H10B 41/50; H10B 43/10; H10B 43/27; H10B 43/35; H10B 43/40

(57) ABSTRACT

A semiconductor device includes a memory cell structure in a first region, a capacitor structure in a second region, and an electrode stacked structure in both the first and second regions. The electrode stacked structure includes a first stacked structure having a plurality of electrodes and a plurality of interlayer insulating layers alternately stacked on each other. The capacitor structure includes the plurality of electrodes, a through electrode penetrating the electrode stacked structure, and a sidewall dielectric layer on a side surface of the through electrode. The sidewall dielectric layer includes first and second dielectric portions. The first dielectric portion is between at least one of the plurality of electrodes and the through electrode. The second dielectric portion is between at least one of the plurality of interlayer insulating layers and the through electrode and extends in a horizontal direction from the first dielectric portion.

### CROSS-REFERENCE TO RELATED APPLICATION

This application claims priority to and the benefit of Korean Patent Application No. 10-2025-0060038 filed with the Korean Intellectual Property Office on May 8, 2025, the entire contents of which are incorporated herein by reference.

### BACKGROUND OF THE INVENTION

### a. Field of the Invention

The present disclosure relates to a semiconductor device and an electronic system including the same, and more particularly, to a semiconductor device with an improved structure and an electronic system including the same.

### b. Description of the Related Art

In an electronic system implementing a data storage, a semiconductor device capable of storing high-capacity data is in demand. Accordingly, a method for increasing a data storage capacity of a semiconductor device is being researched. For example, as one method for increasing a data storage capacity of a semiconductor device, a semiconductor device including three-dimensionally arranged memory cells instead of two-dimensionally arranged memory cells has been proposed.

### SUMMARY OF THE INVENTION

The present disclosure provides a semiconductor device capable of improving performance and productivity and an electronic system including the same.

A semiconductor device according to an embodiment includes an electrode stacked structure, a memory cell structure, and a capacitor structure. The electrode stacked structure is in a first region and a second region in a plan view, and includes a first stacked structure. The first stacked structure includes a plurality of electrodes and a plurality of interlayer insulating layers that are alternately stacked on each other. The memory cell structure is in the first region, and the capacitor structure is in the second region. The capacitor structure includes the plurality of electrodes, a through electrode penetrating the electrode stacked structure, and a sidewall dielectric layer disposed on a side surface of the through electrode. The sidewall dielectric layer includes a first dielectric portion and a second dielectric portion. The first dielectric portion is between at least one of the plurality of electrodes and the through electrode. The second dielectric portion is between at least one of the plurality of interlayer insulating layers and the through electrode and extends in a horizontal direction from the first dielectric portion.

A semiconductor device according to an embodiment includes an electrode stacked structure, a memory cell structure, and a capacitor structure. The electrode stacked structure includes a first stacked region and a second stacked region. The first stacked region has a first stacked structure including a plurality of electrodes and a plurality of interlayer insulating layers that are alternately stacked on each other. The second stacked region has a second stacked structure including the plurality of electrodes and a plurality of dielectric portions that are alternately stacked on each other. The memory cell structure is in the first stacked region, and the capacitor structure is in a portion including the second stacked region. The plurality of dielectric portions have a dielectric constant higher than a dielectric constant of one of the plurality of interlayer insulating layers. The capacitor structure includes the plurality of electrodes, a through electrode penetrating the electrode stacked structure, and a sidewall dielectric layer disposed on a side surface of the through electrode.

An electronic system according to an embodiment includes a main substrate, a semiconductor device disposed on the main substrate, and a controller electrically connected to the semiconductor device disposed on the main substrate. The semiconductor device includes an electrode stacked structure, a memory cell structure, and a capacitor structure. The electrode stacked structure is in a first region and a second region in a plan view, and includes a region having a first stacked structure. The first stacked structure includes a plurality of electrodes and a plurality of interlayer insulating layers that are alternately stacked on each other. The memory cell structure is in the first region, and the capacitor structure is in the second region. The capacitor structure includes the plurality of electrodes, a through electrode penetrating the electrode stacked structure, and a sidewall dielectric layer disposed on a side surface of the through electrode. The sidewall dielectric layer includes a first dielectric portion and a second dielectric portion. The first dielectric portion is between at least one of the plurality of electrodes and the through electrode. The second dielectric portion is between at least one of the plurality of interlayer insulating layers and the through electrode and extends in a horizontal direction from the first dielectric portion.

According to an embodiment, a capacitor structure may include an electrode and/or wiring that is included in a semiconductor device and a sidewall dielectric layer disposed on a side surface of the electrode and/or wiring, thereby achieving a simple structure and large capacitance without requiring an additional area. The sidewall dielectric layer may include a material having a relatively high dielectric constant and may include a first dielectric portion and a second dielectric portion that extends in a horizontal direction from the first dielectric portion, thereby effectively improving the capacitance of the capacitor structure. Accordingly, a capacitor provided in a circuit region may be omitted or reduced and thus an area of the semiconductor device may be reduced. As a result, performance and productivity of the semiconductor device may be improved.

### BRIEF DESCRIPTION OF THE DRAWINGS

FIG. 1 is a plan view schematically illustrating a semiconductor device according to an embodiment.

FIG. 2 is a partial cross-sectional view schematically illustrating a semiconductor device according to an embodiment.

FIG. 3 is an enlarged cross-sectional view illustrating an example of a channel structure included in the semiconductor device illustrated in FIG. 2.

FIG. 4 is an enlarged plan view of a portion C in FIG. 1.

FIG. 5 is a partial cross-sectional view taken along a line D-D' in FIG. 1.

FIG. 6 is a partial cross-sectional view taken along a line E-E' of FIG. 1.

FIG. 7 is a cross-sectional view illustrating a semiconductor device according to an embodiment.

FIG. 8 is another cross-sectional view illustrating the semiconductor device illustrated in FIG. 7.

FIG. 9 is a cross-sectional view illustrating a semiconductor device according to an embodiment.

FIG. 10 is a cross-sectional view illustrating a semiconductor device according to an embodiment.

FIG. 11 is a plan view illustrating a semiconductor device according to an embodiment.

FIG. 12 is a plan view illustrating a semiconductor device according to an embodiment.

FIG. 13 is a plan view illustrating a semiconductor device according to an embodiment.

FIG. 14 is a cross-sectional view illustrating a portion of the semiconductor device illustrated in FIG. 13.

FIG. 15 is a plan view illustrating a semiconductor device according to an embodiment.

FIG. 16 is a plan view illustrating a semiconductor device according to an embodiment.

FIG. 17 is a plan view illustrating a semiconductor device according to an embodiment.

FIG. 18 is a partial cross-sectional view schematically illustrating a semiconductor device according to an embodiment.

FIG. 19 schematically illustrates an electronic system including a semiconductor device according to an embodiment.

FIG. 20 is a perspective view schematically illustrating an electronic system including a semiconductor device according to an embodiment.

FIG. 21 is a cross-sectional view schematically illustrating a semiconductor package according to an embodiment.

FIG. 22 is a cross-sectional view schematically illustrating a semiconductor package according to an embodiment.

### DETAILED DESCRIPTION OF THE EMBODIMENTS

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the embodiments provided herein.

A portion unrelated to the description is omitted in order to clearly describe the present disclosure, and the same or similar components are denoted by the same reference numeral throughout the present specification.

Further, since a size and/or a thickness of a portion, a region, a member, a unit, a layer, a film, a substrate, or the like illustrated in the accompanying drawings may be arbitrarily illustrated for better understanding and convenience of explanation, the present disclosure is not limited to the illustrated size and/or thickness. In the drawings, thicknesses of a portion, a region, a member, a unit, a layer, a film, a substrate, or the like may be enlarged or exaggerated for convenience of explanation and/or simple illustration.

It will be understood that when a component such as a portion, a region, a member, a unit, a layer, a film, a substrate, or the like is referred to as being “on” or “above” another component, it may be directly on or above another component or an intervening component may also be present. In contrast, when a component is referred to as being “directly on” or “directly above” another component, there is no intervening component present. Further, when a component is referred to as being “on” or “above” a reference component, a component may be disposed on, above, or below the reference component, and does not necessarily be “on” or “above” the reference component toward an opposite direction of gravity.

In addition, throughout the specification, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section”, “in a cross-section”, “on a cross-sectional view”, or “in a cross-sectional view” may indicate a vertical cross-sectional view from a side.

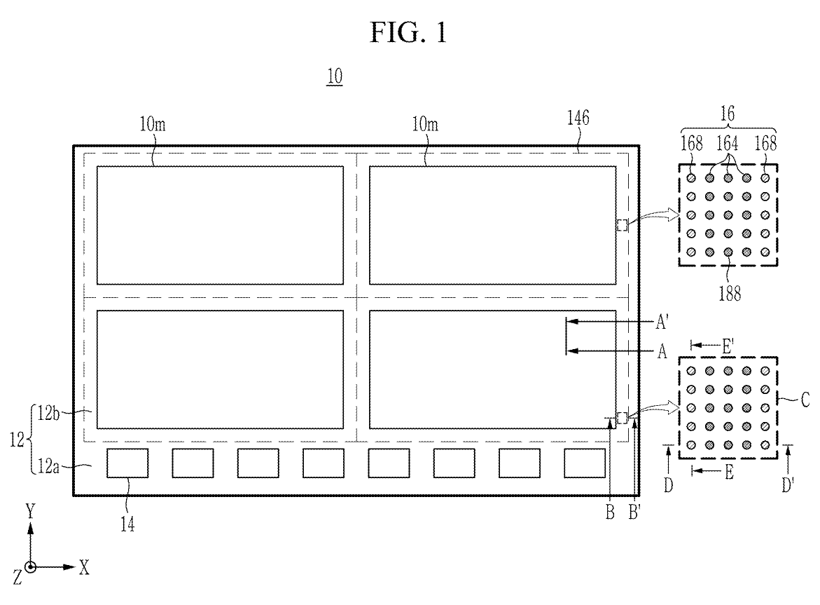

Hereinafter, a semiconductor device and a method of manufacturing the same according to an embodiment will be described in detail with reference to FIGS. 1-6.

FIG. 1 is a plan view schematically illustrating a semiconductor device 10 according to an embodiment. FIG. 1 mainly illustrates a memory region 10m, an outer region 12, an input/output pad 14, a capacitor structure 16, and a separation structure 146 disposed in the outer region 12.

Referring to FIG. 1, in an embodiment, a semiconductor device 10 may include a plurality of memory regions 10m partitioned or divided by an outer region 12.

The memory region 10m is a unit region of the semiconductor device 10 and may be referred to as a MAT. In FIG. 1, it is illustrated as an example that the semiconductor device 10 includes a plurality of memory regions 10m adjacent to each other in a first direction (an X-axis direction in the drawings) and includes a plurality of memory regions 10m adjacent to each other in a second direction (a Y-axis direction in the drawings). However, the embodiments are not limited thereto, and a number, arrangement, or the like of the plurality of memory regions 10m may be variously modified. For example, the semiconductor device 10 may include one memory region 10m, and the outer region 12 may be disposed outside the memory region 10m in a plan view.

The outer region 12 may be configured to separate, divide, or partition the plurality of memory regions 10m, and may be provided between the plurality of memory regions 10m. The outer region 12 may include at least one first outer region 12a longitudinally extending in the first direction (the X-axis direction in the drawings) and at least one second outer region 12b longitudinally extending in the second direction (the Y-axis direction in the drawings). Thereby, a structure of the outer region 12 may be simplified. However, the embodiments are not limited thereto, and the first and/or second outer regions 12a and/or 12b may have a bent portion, a curved portion, or a rounded portion depending on the arrangement of the plurality of memory regions 10m.

An input/output pad 14 for connection with an external circuit may be disposed in the outer region 12. In FIG. 1, it is illustrated as an example that a plurality of input/output pads 14 are disposed to form a single row in a portion adjacent to one edge of the semiconductor device 10. However, the embodiments are not limited thereto, and various modified embodiments are possible. The input/output pads 14 may be disposed adjacent to a plurality of edges of the semiconductor device 10, or may be arranged to have a plurality of rows.

In an embodiment, the semiconductor device 10 may include a capacitor structure 16. For example, the capacitor structure 16 may be used for a positive charge pump or a negative charge pump, or may be used for an input/output capacitor to reduce noise. The embodiments are not limited thereto, and the capacitor structure 16 may perform various roles.

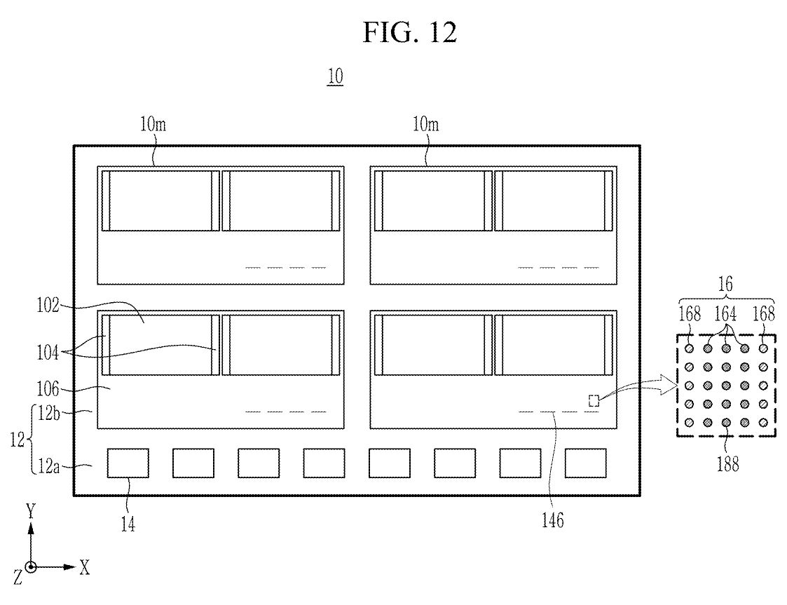

In FIG. 1, it is illustrated as an example that the capacitor structure 16 is disposed in the outer region 12. For example, the capacitor structure 16 may be disposed at any of various positions in a plan view, such as a portion disposed between the plurality of memory regions 10m, a portion disposed between the memory region 10m and the input/output pad 14, a portion overlapping the input/output pad 14, a portion disposed between the input/output pad 14 and the edge of the semiconductor device 10, and/or a portion disposed between the memory region 10m and the edge of the semiconductor device 10. However, the embodiments are not limited thereto. In some embodiments, a position, shape, arrangement, number, or the like of the capacitor structure 16 may be variously modified. For example, the capacitor structure 16 may be disposed in a portion of the memory region 10m, which will be described in detail later with reference to FIG. 12.

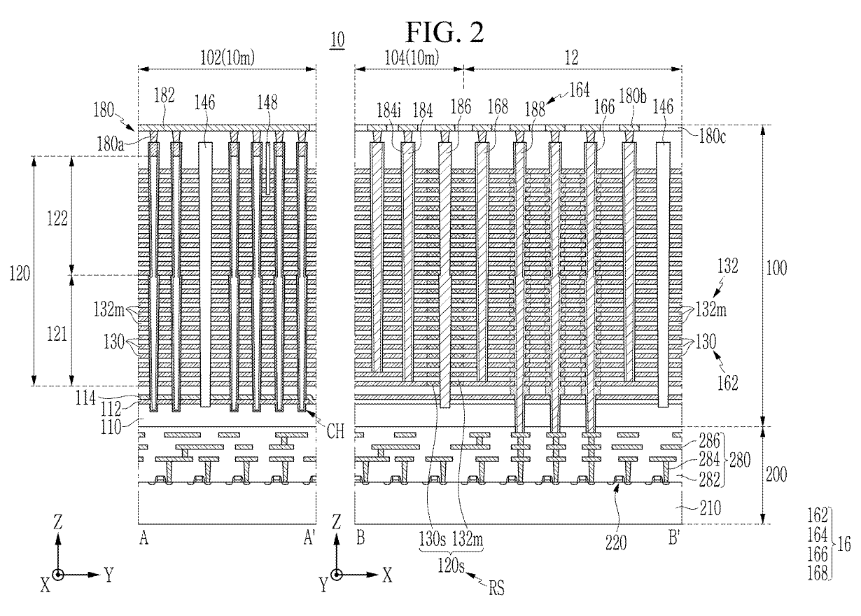

In an embodiment, the capacitor structure 16 may include a first electrode extending in a horizontal direction, a second electrode extending in a direction crossing the horizontal direction (e.g., a vertical direction or a Z-axis direction in the drawings), and a sidewall dielectric layer 166 (refer to FIG. 2) disposed on a side surface of the second electrode between the first electrode and the second electrode. For example, the first electrode may be a gate electrode 130 (refer to FIG. 2), and the second electrode may be a through electrode 164. The capacitor structure 16 may further include a voltage application electrode 168 extending in the direction crossing the horizontal direction (e.g., the vertical direction or the Z-axis direction in the drawings) to apply a voltage to the first electrode. The capacitor structure 16 will be described in more detail later.

A structure (e.g., a separation structure 146) for forming the capacitor structure 16 (e.g., the first electrode) may be provided around the capacitor structure 16. For example, when the capacitor structure 16 is disposed in the outer region 12 as described above, the separation structure 146 may be disposed in the outer region 12. For a clear understanding, the separation structure 146 for forming the capacitor structure 16 in the outer region 12 is illustrated as a dotted line in FIG. 1. The separation structure 146 for forming the capacitor structure 16 in the outer region 12 will be described in more detail later.

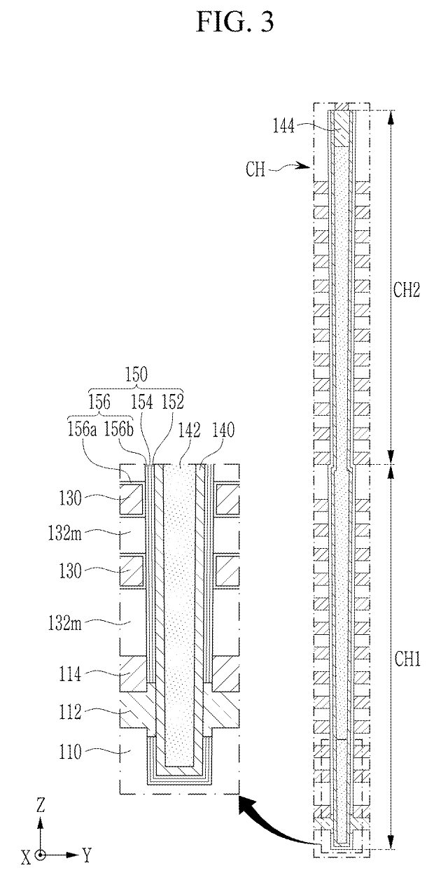

The semiconductor device 10 according to an embodiment will be described in more detail with reference to FIGS. 2-3 along with FIG. 1.

FIG. 2 is a partial cross-sectional view schematically illustrating the semiconductor device 10 according to an embodiment, and FIG. 3 is an enlarged cross-sectional view illustrating an example of a channel structure CH included in the semiconductor device 10 illustrated in FIG. 2. FIG. 2 is a cross-sectional view taken along a line A-A' and a line B-B' in FIG. 1. For a clear understanding, a gate contact 184, a source contact 186, and an input/output connection wiring 188 or a through electrode 164 of a capacitor structure 16 are illustrated together in FIG. 2, and an arrangement of the source contact 186, and the input/output connection wiring 188 or the through electrode 164 of the capacitor structure 16 is conceptually illustrated. The positions of the gate contact 184, the source contact 186, and the input/output connection wiring 188 or the through electrode 164 of the capacitor structure 16 may be variously modified.

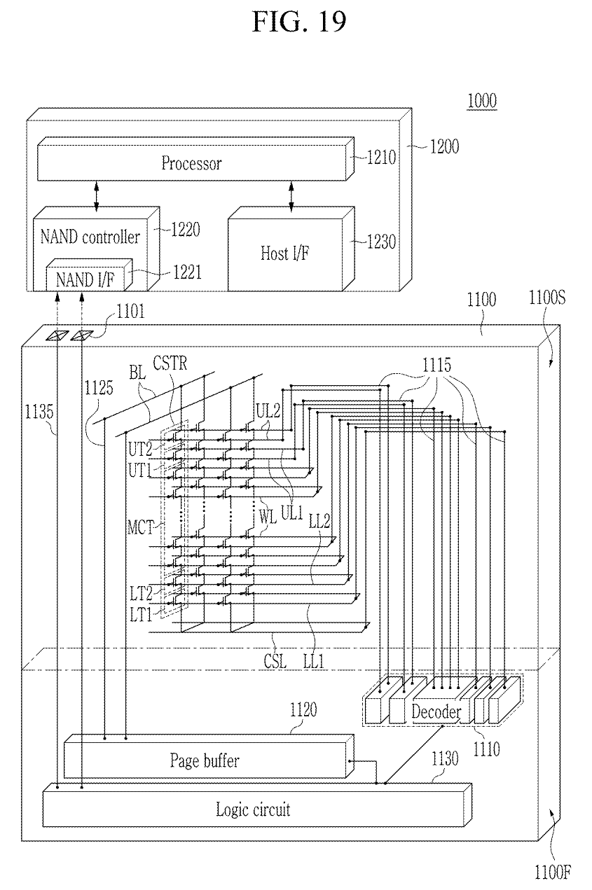

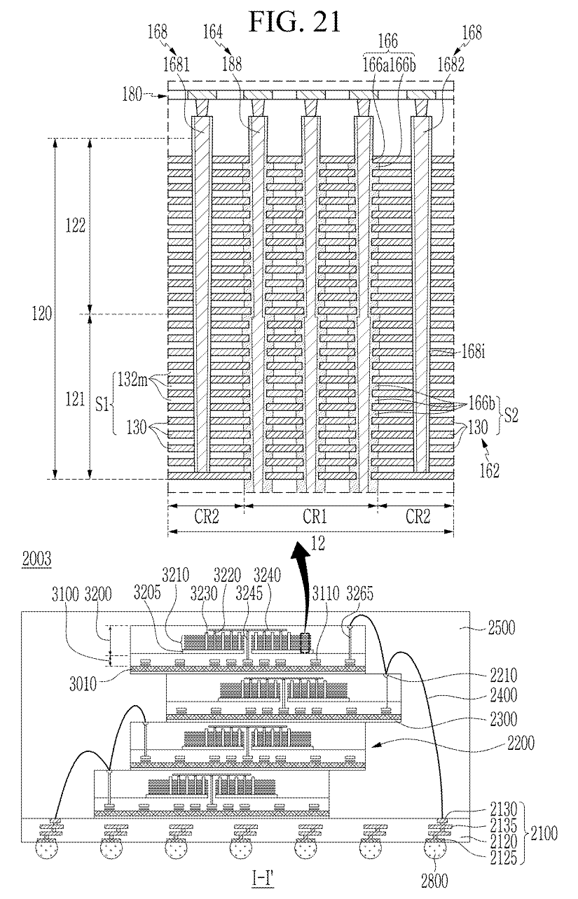

Referring to FIGS. 1-3, a semiconductor device 10 according to an embodiment may include a cell region 100 where a memory cell structure is provided, and a circuit region 200 where a peripheral circuit structure for controlling an operation of the memory cell structure is provided. For example, the circuit region 200 and the cell region 100 may be portions corresponding to a first structure 1100F and a second structure 1100S of a semiconductor device 1100 included in an electronic system 1000 illustrated in FIG. 19, respectively. For example, the circuit region 200 and the cell region 100 may be portions including a first structure 3100 and a second structure 3200 of a semiconductor chip 2200 illustrated in FIG. 21, respectively.

The circuit region 200 may include a peripheral circuit structure disposed on a first substrate 210, and the cell region 100 may include a memory cell structure disposed on a second substrate 110. A circuit wiring portion 280 may be provided in the circuit region 200, and a cell wiring portion 180 electrically connected to the memory cell structure may be provided in the cell region 100.

In an embodiment, the cell region 100 may be disposed on the circuit region 200. Thereby, a region corresponding to the circuit region 200 may not be needed separately from the cell region 100, and an area of the semiconductor device 10 may be reduced. However, the embodiments are not limited thereto, and the circuit region 200 may be disposed next to the cell region 100. Other various modified embodiments are possible.

The circuit region 200 may include a first substrate 210, a circuit element 220, and a circuit wiring portion 280, and may be electrically connected to the cell region 100.

The first substrate 210 may be a semiconductor substrate including a semiconductor material. For example, the first substrate 210 may be a semiconductor substrate formed of a semiconductor material or a semiconductor substrate in which a semiconductor layer is disposed on a base substrate. For example, the first substrate 210 may include or be formed of a semiconductor material (e.g., silicon, germanium, silicon-germanium, or the like) having a single crystal structure, an epitaxial structure, or a polycrystalline structure, or may include or be formed of silicon on insulator (SOI), germanium on insulator (GOI), or the like.

The circuit element 220 on the substrate 210 may include any of various circuit elements to constitute the peripheral circuit structure that controls the operation of the memory cell structure provided in the cell region 100. For example, the circuit element 220 may constitute a peripheral circuit structure such as a decoder circuit 1110 (refer to FIG. 19), a page buffer 1120 (refer to FIG. 19), or a logic circuit 1130 (refer to FIG. 19).

For example, the circuit element 220 may include a transistor, but the embodiments are not limited thereto. For example, the circuit element 220 may include not only an active element such as a transistor, but also a passive element such as a capacitor, a resistor, or an inductor.

The circuit wiring portion 280 on the first substrate 210 may be electrically connected to the circuit element 220. In an embodiment, the circuit wiring portion 280 may include a plurality of wiring layers 286 spaced apart from each other while interposing an insulating layer 282 therebetween and connected by a contact via 284 to form a desired path. The wiring layer 286 or the contact via 284 may include any of various conductive materials, and the insulating layer 282 may include any of various insulating materials. For example, the insulating layer 282 may include or be formed of at least one of silicon oxide, silicon nitride, and silicon oxynitride.

In an embodiment, the cell region 100 may be a region including a gate stacked structure 120, a memory cell structure, and a capacitor structure 16. The memory cell structure may include at least a portion of the gate stacked structure 120 and a channel structure CH to perform a memory operation. For a clear understanding, the memory cell structure and the gate stacked structure 120 are described separately in this specification, but at least a portion of the gate stacked structure 120 may be included in the memory cell structure.

In the memory region 10m, the cell region 100 may include a cell array region 102 and a connection region 104. In the cell array region 102, the gate stacked structure 120 and the channel structure CH may be provided as a memory cell structure on the second substrate 110. A structure for connecting the gate stacked structure 120 and/or the channel structure CH in the cell array region 102 to the circuit region 200 or an external circuit may be disposed in the cell array region 102 and/or the connection region 104. In the memory region 10m, the cell region 100 may further include a dummy region 106 (refer to FIG. 12) other than the cell array region 102 and the connection region 104. This will be described in more detail later with reference to FIG. 12.

In an embodiment, the second substrate 110 may include a semiconductor layer including a semiconductor material. For example, the second substrate 110 may be a semiconductor substrate formed of a semiconductor material or a semiconductor substrate in which a semiconductor layer is disposed on a base substrate. For example, the second substrate 110 may include a semiconductor material (e.g., silicon, germanium, silicon-germanium, or the like) having a single crystal structure, an epitaxial structure, or a polycrystalline structure, or may be formed of silicon on insulator, germanium on insulator, or the like. The semiconductor layer included in the second substrate 110 may be doped with a p-type or n-type dopant. For example, the p-type dopant may include boron (B), gallium (Ga), or the like, and the n-type dopant may include phosphorus (P), arsenic (As), or the like. However, the embodiments are not limited to the material of the second substrate 110, the conductivity type or the material of the dopant doped in the semiconductor layer, or the like.

In the cell array region 102, the gate stacked structure 120 and the channel structure CH may be disposed. The gate stacked structure 120 may include a cell insulating layer 132 (e.g., an interlayer insulating layer 132m) and a gate electrode 130 alternately stacked on a first surface (an example, a front surface or an upper surface) of the second substrate 110. The channel structure CH may extend to penetrate the gate stacked structure 120. For example, an extension direction of the channel structure CH may be a thickness direction of the semiconductor device 10, a vertical direction, or an Z-axis direction.

In an embodiment, in the cell array region 102, horizontal conductive layers 112 and 114 that electrically connect (an example, directly connect) the channel structure CH and the second substrate 110 may be included between the second substrate 110 and the gate stacked structure 120. The horizontal conductive layers 112 and 114 may include a first horizontal conductive layer 112 and/or a second horizontal conductive layer 114 sequentially disposed on the second substrate 110. The first horizontal conductive layer 112 may act as a portion of a common source line of the semiconductor device 10. For example, the first horizontal conductive layer 112 may acts as a common source line together with the second substrate 110.

The first and second horizontal conductive layers 112 and 114 may include a semiconductor material (e.g., polycrystalline silicon). For example, the first horizontal conductive layer 112 may include a polycrystalline silicon layer including a dopant. However, the embodiments are not limited thereto. In some embodiments, the second horizontal conductive layer 114 may be formed of a material (e.g., an insulating material) different from a material of the first horizontal conductive layer 112, or the second horizontal conductive layer 114 may be omitted.

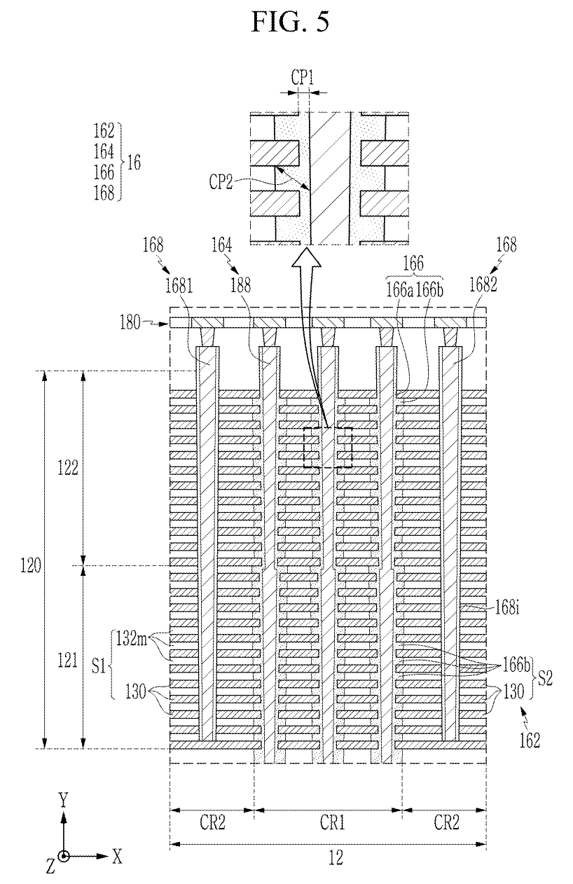

The gate stacked structure 120 including a region where a plurality of interlayer insulating layers 132m and a plurality of gate electrodes 130 are alternately stacked on each other may be disposed on the second substrate 110 (an example, on the first and second horizontal conductive layers 112 and 114 on the second substrate 110). For example, the gate stacked structure 120 may include a first stacked region having a first stacked structure S1 (refer to FIG. 5) and a second stacked region having a second stacked structure S2 (refer to FIG. 5). In the first stacked structure S1, a plurality of interlayer insulating layers 132m and a plurality of gate electrodes 130 may be alternately stacked on each other. In the second stacked structure S2, a plurality of gate electrodes 130 and a plurality of dielectric portions (e.g., a plurality of second dielectric portions 166b (refer to FIG. 5) of a sidewall dielectric layer 166) may be included. The second stacked structure S2 will be described in detail later.

The gate electrode 130 may include any of various conductive materials. For example, the gate electrode 130 may include a metal material, a semiconductor material, metal nitride, or a combination thereof. The metal material may include tungsten (W), titanium (Ti), tantalum (Ta), copper (Cu), aluminum (Al), cobalt (Co), molybdenum (Mo), or ruthenium (Ru), or may include an alloy including at least one of the above materials. The semiconductor material may include polycrystalline silicon. The metal nitride may include tungsten nitride (WN), titanium nitride (TiN), tantalum nitride (TaN), or the like. As illustrated in an enlarged view of FIG. 3, a portion (e.g., a first blocking layer 156a) of a blocking layer 156 formed of an insulating material may be disposed on an outside of the gate electrode 130.

The interlayer insulating layer 132m may include any of various insulating materials. For example, the interlayer insulating layer 132m may include or be formed of silicon oxide, silicon nitride, silicon oxynitride, a low dielectric constant material having a dielectric constant lower than a dielectric constant of silicon oxide, or a combination thereof.

However, the material, structure, or the like of the gate electrode 130 or the interlayer insulating layer 132m may be variously modified, and the embodiments are not limited thereto.

In an embodiment, the channel structure CH may include a channel layer 140, and a gate dielectric layer 150 disposed on the channel layer 140 between the gate electrode 130 and the channel layer 140. The channel structure CH may further include a core insulating layer 142 disposed inside the channel layer 140, but the core insulating layer 142 may be omitted in some embodiments. The channel structure CH may further include a channel pad 144 disposed on the channel layer 140 and/or the gate dielectric layer 150.

Each channel structures CH may form a memory cell string, and a plurality of channel structures CH may be spaced apart from each other to form rows and columns in a plan view. For example, a plurality of channel structures CH may be arranged in any of various forms such as a lattice shape, a zigzag shape, or the like in a plan view. The channel structure CH may have a pillar shape. For example, the channel structure CH may have an inclined side surface such that a width of the channel structure CH decrease toward the second substrate 110 due to an aspect ratio in a cross-sectional view. However, the embodiments are not limited thereto, and the arrangement, structure, shape, or the like of the channel structure CH may be variously modified.

The channel layer 140 may include a semiconductor material, for example, a semiconductor material (e.g., silicon) having a polycrystalline, epitaxial, or single crystal structure. The core insulating layer 142 may include any of various insulating materials. For example, the core insulating layer 142 may include silicon oxide, silicon nitride, silicon oxynitride, or a combination thereof.

The gate dielectric layer 150 disposed between the gate electrode 130 and the channel layer 140 may include a tunneling layer 152, a charge storage layer 154, and a blocking layer 156 sequentially disposed on the channel layer 140.

The tunneling layer 152 may include or be formed of an insulating material (e.g., silicon oxide, silicon oxynitride, or the like) capable of charge tunneling. The charge storage layer 154 may be used as a data storage region, and the charge storage layer 154 may include or be formed of polycrystalline silicon, silicon nitride, or the like. The blocking layer 156 may include an insulating material that may prevent charges from undesirably flowing into the gate electrode 130. For example, the blocking layer 156 may include or be formed of silicon oxide, silicon nitride, silicon oxynitride, a high dielectric constant material having a dielectric constant higher than a dielectric constant of silicon oxide, or a combination thereof. In an embodiment, the blocking layer 156 may include a first blocking layer 156a including a portion extending horizontally along the gate electrode 130, and a second blocking layer 156b extending vertically between the first blocking layer 156a and the charge storage layer 154.

The channel pad 144 may cover one surface of the core insulating layer 142 (e.g., one surface of the core insulating layer 142 opposite to the circuit region 200) and be electrically connected to the channel layer 140. The channel pad 144 may include or be formed of a conductive material, for example, a semiconductor material doped with a dopant, for example, a polycrystalline or epitaxial semiconductor material (e.g., silicon) doped with a dopant, but the embodiments are not limited thereto.

The material, structure, or the like of the channel layer 140, the core insulating layer 142, the gate dielectric layer 150, or the channel pad 144 may be variously modified, and the embodiments are not limited thereto.

In an embodiment, the gate stacked structure 120 may include a plurality of gate stacked portions 121 and 122 sequentially stacked on each other. Thereby, a number of stacked gate electrodes 130 may be increased, and a number of memory cells may increase with a stable structure. In FIG. 2, it is illustrated as an example that the gate stacked structure 120 includes a first gate stacked portion 121 and a second gate stacked portion 122, but the gate stacked structure 120 may include one or three or more gate stacked structures.

When the plurality of gate stacked portions 121 and 122 are provided as described above, the channel structure CH may include a plurality of channel portions CH1 and CH2. The plurality of channel portions CH1 and CH2 may penetrate the plurality of gate stacked portions 121 and 122, respectively, and may be connected to each other. Each of the plurality of channel portions CH1 and CH2 may have an inclined side surface such that a width of each of the plurality of channel portions CH1 and CH2 decreases toward the second substrate 110 due to an aspect ratio in a cross-sectional view. A bent portion due to a width difference may be provided at a boundary of the plurality of channel portions CH1 and CH2. In some embodiments, the plurality of channel portions CH1 and CH2 may have an inclined side surface that is continuously connected without a bent portion. In FIG. 3, it is illustrated as an example that each of the gate dielectric layer 150, the channel layer 140, and the core insulating layer 142 of the plurality of channel portions CH1 and CH2 extend to have an integral structure. In some embodiments, at least one of the gate dielectric layers 150, the channel layers 140, and the core insulating layers 142 of the plurality of channel portions CH1 and CH2 may be formed separately from each other and be electrically connected to each other, or a separate channel pad may be additionally provided at the boundary of the plurality of channel portions CH1 and CH2. As such, the embodiments are not limited to the shape of the plurality of channel portions CH1 and CH2.

In an embodiment, in the memory region 10m, the gate stacked structure 120 may be partitioned into a plurality of portions in a plan view by a separation structure 146 that extends in the thickness direction of the semiconductor device 10 or the vertical direction (the Z-axis direction in the drawings) and penetrates the gate stacked structure 120. A separation pattern 148 may be formed on an upper portion of the gate stacked structure 120. In a plan view, the separation structures 146 and/or the separation pattern 148 may extend in an extension direction of the gate electrode 130 (the X-axis direction in the drawings), and a plurality of separation structures 146 and/or separation patterns 148 may be spaced apart from each other by a predetermined distance in a direction crossing the gate electrode 130 (the Y-axis direction in the drawings).

In the memory region 10m, by the separation structure 146, a plurality of gate stacked structures 120 may extend in a first direction (the X-axis direction in the drawings) and be spaced apart from each other by a predetermined distance in a second direction (the Y-axis direction in the drawings) crossing the first direction in a plan view. In the memory region 10m, the gate stacked structure 120 partitioned by the separation structure 146 may constitute one memory cell block. However, the embodiments are not limited thereto, and a range of the memory cell block is not limited thereto.

For example, the separation structure 146 may penetrate the gate stacked structure 120, and the separation pattern 148 may separate one or a portion of the plurality of gate electrodes 130 from each other. The separation pattern 148 may be disposed between the separation structures 146. In a cross-sectional view, the separation structure 146 or the separation pattern 148 may extend in the thickness direction of the semiconductor device 10 or the vertical direction (the Z-axis direction in the drawings) to penetrate the gate stacked structure 120.

In FIG. 2, it is illustrated as an example that the separation structure 146 has an inclined side surface in which a width of the separation structure 146 gradually decreases toward the second substrate 110 due to a high aspect ratio in a cross-sectional view, and a bent portion due to a width difference is not provided in the separation structure 146 at a boundary of the plurality of gate stacked portions 121 and 122. However, the embodiments are not limited thereto, and the side surface of the separation structure 146 may be parallel to the thickness direction of the semiconductor device 10 or the vertical direction (the Z-axis direction in the drawings), or the bent portion may be provided in the separation structure 146 at the boundary of the plurality of gate stacked portions 121 and 122. The separation structure 146 may have any of various shapes.

The separation structure 146 or the separation pattern 148 may include any of various insulating materials. For example, the separation structure 146 or the separation pattern 148 may include or be formed of an insulating material such as silicon oxide, silicon nitride, or silicon oxynitride. However, the embodiments are not limited thereto, and the structure, shape, material, or the like of the separation structure 146 or the separation pattern 148 may be variously modified.

The connection region 104 and/or the outer region 12, and the cell wiring portion 180 may be provided to connect the gate stacked structure 120 and the channel structure CH provided in the cell array region 102 to the circuit region 200 or an external circuit. The connection region 104 may be disposed around or outside the cell array region 102, and a portion of the cell wiring portion 180 may be disposed in the connection region 104.

The cell wiring portion 180 may include all members that electrically connect the gate electrode 130, the channel structure CH, the horizontal conductive layers 112 and 114, and/or the second substrate 110 to the circuit region 200 or an external circuit. For example, the cell wiring portion 180 may include a bit line 182, a gate contact 184, a source contact 186, an input/output connection wiring 188, a contact via 180a, and a connection wiring 180b. The contact via 180a may be connected to the bit line 182, the gate contact 184, the source contact 186, and/or the input/output connection wiring 188. The connection wiring 180b may be connected to the contact via 180a, the bit line 182, the gate contact 184, the source contact 186, and/or the input/output connection wiring 188. For a clear understanding, the horizontal conductive layers 112 and 114 are described separately from the cell wiring portion 180, but the horizontal conductive layers 112 and 114 may be a portion of the cell wiring portion 180.

The bit line 182 may extend in a crossing direction (the Y-axis direction in the drawings) crossing the extension direction of the gate electrode 130 (the X-axis direction in the drawings). The bit line 182 may be electrically connected to the channel structure CH (e.g., the channel pad 144) through a contact via 180a (e.g., a bit line contact via) that penetrates a portion of the cell insulating layer 132 disposed on the gate stacked structure 120.

In an embodiment, a plurality of gate electrodes 130 may extend to be disposed in the connection region 104. In the connection region 104, a plurality of gate contacts 184 may penetrate the gate stacked structure 120 or the cell insulating layer 132 to be electrically connected to the plurality of gate electrodes 130 extended to the connection region 104, respectively. A side insulating layer 184i may be disposed on a side surface of each gate contact 184.

For example, in the connection region 104, a plurality of contact holes in which the side insulating layer 184i and the gate contact 184 are respectively disposed may be individually provided in the gate stacked structure 120, and the gate stacked structure 120 may be disposed entirely in a portion excluding the separation structure 146 and/or the separation pattern 148. For example, in the connection region 104, extension lengths of the plurality of gate electrodes 130 may be substantially the same. Being substantially the same may include the case of having a difference within a process error (e.g., within 10%). In this instance, the side insulating layer 184i may be disposed on the side surface of the gate contact 184, and an end (a lower end in FIG. 2) of the gate contact 184 may be electrically connected to (e.g., in contact with) the gate electrode 130.

In FIG. 2, it is illustrated as an example that the gate contact 184 has an inclined side surface in which a width of the gate contact 184 gradually decreases toward the second substrate 110 due to a high aspect ratio in a cross-sectional view, and a bent portion due to a width difference is not provided at the boundary of the plurality of gate stacked portions 121 and 122. However, the embodiments are not limited thereto, and the side surface of the gate contact 184 may be parallel to the thickness direction of the semiconductor device 10 or the vertical direction (the Z-axis direction in the drawings), or the bent portion may be provided at the boundary of the plurality of gate stacked portions 121 and 122. The gate contact 184 may have other various shapes.

In an embodiment, a portion (e.g., a pad region) where the gate stacked structure 120 is removed in a stepped shape for an electrical connection of the gate electrode 130 and the gate contact 184 and an insulating layer (e.g., a pad insulating layer) on the portion may be omitted. Accordingly, a process of electrically connecting the gate contact 184 and the gate electrode 130 may be simplified, and an area of the connection region 104 may be reduced.

However, the embodiments are not limited thereto. In some embodiments, in the connection region 104, the extension lengths of the plurality of gate electrodes 130 may sequentially decrease far away from the second substrate 110. For example, the plurality of gate electrodes 130 may have a stepped shape in one direction or a plurality of directions in the connection region 104, and the gate stacked structure 120 may include a portion (e.g., a pad region) removed in a stepped shape. A plurality of gate contacts 184 may penetrate the cell insulating layer 132 (e.g., a pad insulating layer) in the pad region and may be electrically connected to the plurality of gate electrodes 130, respectively. Besides, an electrical connection structure of the gate electrode 130 and the gate contact 184 may be variously modified.

An insulating stacked structure 120s may be disposed in at least a portion of the connection region 104. The insulating stacked structure 120s may include a plurality of cell insulating layers 132 (e.g., interlayer insulating layers 132m) and a plurality of sacrificial insulating layers 130s that are alternately stacked on each other. The plurality of sacrificial insulating layers 130s of the insulating stacked structure 120s may be provided to correspond to the plurality of gate electrodes 130 of the gate stacked structure 120, respectively. The plurality of interlayer insulating layers 132m of the insulating stacked structure 120s may be provided to correspond to the plurality of interlayer insulating layers 132m of the gate stacked structure 120, respectively. The sacrificial insulating layer 130s may include a material different from the interlayer insulating layer 132m. For example, the sacrificial insulating layer 130s may include or be formed of silicon, silicon oxide, silicon carbide, silicon nitride, silicon oxynitride, or the like, and may include a material different from the interlayer insulating layer 132m.

The plurality of interlayer insulating layers 132m of the gate stacked structure 120 and the plurality of interlayer insulating layers 132m of the insulating stacked structure 120s may be formed in the same process. The insulating stacked structure 120s may be formed by alternately stacking the plurality of interlayer insulating layers 132m and the plurality of sacrificial insulating layers 130s in at least a portion of the cell array region 102, the connection region 104, and the outer region 12. Thereafter, the plurality of sacrificial insulating layers 130s disposed in at least a portion of the cell array region 102, the connection region 104, and the outer region 12 may be selectively removed, and the gate electrodes 130 may be formed in the portions where the sacrificial insulating layers 130s are removed. For example, a plurality of gate electrodes 130 may be formed by a replacement process of replacing the plurality of sacrificial insulating layers 130s with the plurality of gate electrodes 130 using an opening for a separation structure where the separation structure 146 is disposed.

Accordingly, the gate stacked structure 120 in which the plurality of interlayer insulating layers 132m and the plurality of gate electrodes 130 are alternately stacked on each other may be disposed in at least a portion of the cell array region 102, the connection region 104, and the outer region 12, and the insulating stacked structure 120s in which the plurality of interlayer insulating layers 132m and the plurality of sacrificial insulating layers 130s are alternately stacked on each other may be disposed in at least a portion of the connection region 104.

By forming the gate stacked structure 120 using the insulating stacked structure 120s as described above, the gate stacked structure 120 including a large number of gate electrodes 130 may be easily formed. In contrast, in a comparative example in which a gate stacked structure is formed without an insulating stacked structure, a process of forming a channel structure, a gate contact, a source contact, an input/output connection wiring, or the like that penetrate the gate stacked structure may be difficult. As a result, there may be a limit to increasing the number of gate electrodes included in the gate stacked structure.

In FIG. 2, it is illustrated as an example that the source contact 186 is formed of a conductive portion and penetrates the insulating stacked structure 120s to be electrically connected to the horizontal conductive layers 112 and 114 and/or the second substrate 110. However, the embodiments are not limited thereto. In some embodiments, the source contact 186 may penetrate the cell insulating layer 132. In some embodiments, the source contact 186 may include a conductive portion and a side insulating layer like the gate contact 184, and may penetrate the gate stacked structure 120, the insulating stacked structure 120s, or the cell insulating layer 132.

The input/output connection wiring 188 may penetrate the gate stacked structure 120 or be disposed outside the gate stacked structure 120 to be electrically connected to the circuit wiring portion 280 of the circuit region 200. In the drawings, it is illustrated as an example that the input/output connection wiring 188 penetrates the gate stacked structure 120 and/or the second substrate 110, and an insulating layer (e.g., a sidewall dielectric layer 166) is disposed on a side surface of the input/output connection wiring 188 between the input/output connection wiring 188 and the gate stacked structure 120 and/or between the input/output connection wiring 188 and the second substrate 110. However, the embodiments are not limited thereto. In some embodiments, in a portion where at least one of the plurality of input/output connection wirings 188 is disposed, the gate stacked structure 120 may not be provided and an insulating stacked structure 120s or a cell insulating layer 132 may be disposed, and at least one of the plurality of input/output connection wirings 188 may penetrate the insulating stacked structure 120s or the cell insulating layer 132. An insulating layer may be disposed or may not be disposed on a side surface of the input/output connection wiring 188 that penetrates the insulating stacked structure 120s or the cell insulating layer 132.

In FIG. 2, it is illustrated as an example that the source contact 186 and/or the input/output connection wiring 188 has an inclined side surface such that a width of the source contact 186 and/or the input/output connection wiring 188 decreases toward the second substrate 110 due to an aspect ratio in a cross-sectional view, and has a bent portion at the boundary of the plurality of gate stacked portions 121 and 122. However, the embodiments are not limited thereto. The source contact 186 and/or the input/output connection wiring 188 may not have a bent portion at the boundary of the plurality of gate stacked portions 121 and 122. Other various modified embodiments are possible.

In FIG. 2, it is illustrated as an example that the connection wiring 180b is provided as a single layer disposed on the same plane as the bit line 182, and an insulating layer 180c is disposed in a portion other than the cell wiring portion 180. However, the embodiments are not limited thereto. In some embodiments, a plurality of connection wirings 180b may be provided and may be disposed on different layers for electrical connection with the bit line 182, the gate contact 184, the source contact 186, and/or the input/output connection wiring 188, and a contact via that electrically connects the plurality of connection wirings may be further included.

The cell wiring portion 180 may be electrically connected to the circuit wiring portion 280 such that the bit line 182 electrically connected to the channel structure CH, the gate electrode 130, the horizontal conductive layers 112 and 114, and/or the second substrate 110 is electrically connected to the circuit element 220 of the circuit region 200.

In an embodiment, the gate stacked structure 120 (e.g., the gate electrode 130) and the cell wiring portion 180 (e.g., the input/output connection wiring 188) may constitute the capacitor structure 16. For example, the gate stacked structure 120 may be disposed in a first region and a second region in a plan view. The first region may be a region where the memory cell structure (e.g., the gate stacked structure 120 and the channel structure CH) is disposed, and the second region may be a region other than the first region and a region where the capacitor structure 16 is disposed. That is, the capacitor structure 16 may be formed using the gate stacked structure 120 (e.g., the gate electrode 130) and the cell wiring portion 180 (e.g., the input/output connection wiring 188) disposed in the second region other than the first region where the memory cell structure is disposed.

As described above, in an embodiment, the capacitor structure 16 may be disposed in the outer region 12. In this instance, the cell array region 102 and at least a portion of the connection region 104 may correspond to the first region, and at least a portion of the outer region 12 may correspond to the second region. When the capacitor structure 16 is disposed in the outer region 12 as described above, the gate electrode 130 may be provided in the outer region 12. Accordingly, in the outer region 12, a structure (e.g., the separation structure 146) for replacing the sacrificial insulating layer 130s with the gate electrode 130 may be disposed.

In FIG. 1, it is illustrated as an example that the separation structure 146 disposed in the outer region 12 has a shape that extends along an edge of the memory region 10m, and has a frame shape that surrounds one memory region 10m when viewed based on one memory region 10m. Accordingly, when viewed based on one memory region 10m, the gate stacked structure 120 disposed in the outer region 12 may have a shape that entirely surrounds the memory region 10m. According to this, the sacrificial insulating layer 130s of the insulating stacked structure 120s may be stably replaced with the gate electrode 130 of the gate stacked structure 120 in the outer region 12, and the gate stacked structure 120 may be stably formed in the outer region 12. Further, by increasing an area of the gate stacked structure 120 in the outer region 12, a region where the capacitor structure 16 is disposed may increase.

However, the embodiments are not limited thereto, and the shape, position, and arrangement of the separation structure 146 disposed in the outer region 12, the position and arrangement of the gate stacked structure 120, or the like may be variously modified.

In the above description, it is described as an example that the structure for replacing the sacrificial insulating layer 130s with the gate electrode 130 in the outer region 12 is the separation structure 146. According to this, since an additional structure for replacing the sacrificial insulating layer 130s with the gate electrode 130 is not provided in the outer region 12, a structure and manufacturing process may be simplified. However, the embodiments are not limited thereto, and the structure or manufacturing process for replacing the sacrificial insulating layer 130s with the gate electrode 130 in the outer region 12 may be variously modified.

In an embodiment, a regional separation portion RS may electrically separate the plurality of gate electrodes 130 disposed in the first region and the plurality of gate electrodes 130 disposed in the second region may be provided such that the driving of the memory cell structure and the driving of the capacitor structure 16 are performed independently. By the regional separation portion RS, the capacitor structure 16 may operate freely and stably.

In an embodiment, the regional separation portion RS may be an insulating stacked structure 120s disposed between the first region (e.g., the cell array region 102 and/or the connection region 104) and the second region (e.g., the outer region 12). By leaving the insulating stacked structure 120s between the first region and the second region, the gate electrodes 130 in the first region and the gate electrodes 130 in the second region may be electrically separated without additionally forming a regional separation portion. As a result, the structure and manufacturing process may be simplified.

However, the embodiments are not limited thereto, and the first region and the second region may be electrically separated by any of various structures, schemes, or methods. In some embodiments, the first region and the second region may not be electrically separated, and the capacitor structure 16 may be driven using the driving of the gate contact 184. For example, a voltage may be applied to the gate electrode 130, which is a first electrode of the capacitor structure 16, using a voltage applied to the gate contact 184. Other various modified embodiments are possible.

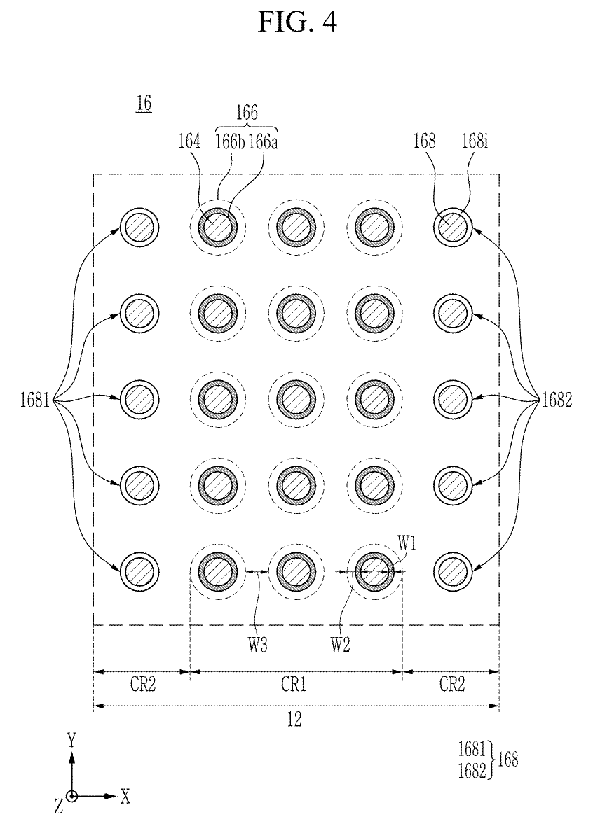

The capacitor structure 16 will be described in detail with reference to FIGS. 4-6.

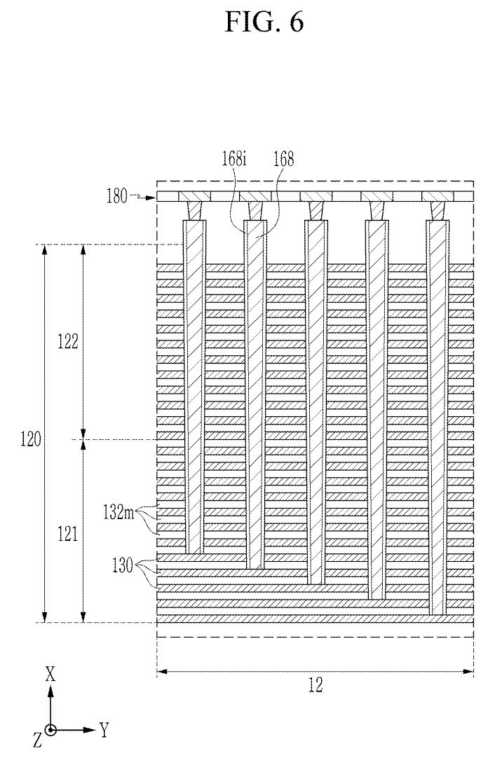

FIG. 4 is an enlarged plan view of a portion C in FIG. 1. FIG. 5 is a partial cross-sectional view taken along a line D-D' in FIG. 1, and FIG. 6 is a partial cross-sectional view taken along a line E-E' of FIG. 1. In FIG. 4, a portion of the cell insulating layer 132 disposed on the gate stacked structure 120 is omitted, and the through electrode 164, the sidewall dielectric layer 166, and the voltage application electrode 168 included in the capacitor structure 16 are mainly illustrated.

Referring to FIGS. 4-6, in an embodiment, the capacitor structure 16 may include a plurality of gate electrodes 130 included in the gate stacked structure 120, the through electrode 164 penetrating the gate stacked structure 120, and the sidewall dielectric layer 166 disposed on a side surface of the through electrode 164. The capacitor structure 16 may further include a voltage application electrode 168 that penetrates the gate stacked structure 120 in the second region to apply a voltage to the plurality of gate electrodes 130.

The plurality of gate electrodes 130 may correspond to a horizontal electrode 162 or a first electrode extending in the horizontal direction (a direction parallel to an XY plane in the drawings), the through electrode 164 may correspond to a vertical electrode or a second electrode extending in a direction crossing the horizontal direction (e.g., the thickness direction of the semiconductor device 10 or the vertical direction (the Z-axis direction in the drawings)), and the sidewall dielectric layer 166 may correspond to a dielectric layer disposed between the first electrode and the second electrode. For example, the capacitor structure 16 may be a metal-insulator-metal (MIM) capacitor including the first electrode, the second electrode, and the dielectric layer, and may be a vertical capacitor including the vertical electrode.

The voltage application electrode 168 may correspond to a third electrode that penetrates the gate stacked structure 120 separately from the through electrode 164 or the second electrode to apply a voltage to the gate electrode 130 or the first electrode corresponding to the horizontal electrode 162. The voltage application electrode 168 may be provided separately from the gate contact 184 in the second region, and the driving of the memory cell structure and the driving of the capacitor structure 16 may be performed independently. As a result, the capacitor structure 16 may operate freely and stably. However, the embodiments are not limited thereto. In some embodiments, without separately providing the voltage application electrode 168, the capacitor structure 16 may be driven using the driving of the gate contact 184. For example, a voltage may be applied to the gate electrode 130, which is the first electrode of the capacitor structure 16, using a voltage applied to the gate contact 184. Other various modified embodiments are possible.

In an embodiment, the second region where the capacitor structure 16 is disposed may include a first capacitor region CR1 and a second capacitor region CR2. The through electrode 164 is disposed in the first capacitor region CR1, and the voltage application electrode 168 is disposed in the second capacitor region CR2. This will be described in more detail after describing the through electrode 164 and the voltage application electrode 168.

In an embodiment, the capacitor structure 16 may include the plurality of gate electrodes 130 included in the gate stacked structure 120 as the horizontal electrode 162 or the first electrode. By including the plurality of gate electrodes 130 as the first electrode as described above, an additional process of forming the first electrode included in the capacitor structure 16 may be omitted, and a manufacturing process may be simplified and an area of the semiconductor device 10 may be reduced.

In an embodiment, the capacitor structure 16 may include the input/output connection wiring 188, which is included in the cell wiring portion 180 and is connected to the circuit region 200 (e.g., the wiring layer 286), as the through electrode 164 or the second electrode. By including the input/output connection wiring 188 as the through electrode 164 or the second electrode as described above, an additional process of forming the second electrode included in the capacitor structure 16 may be omitted, and a manufacturing process may be simplified and an area of the semiconductor device 10 may be reduced.

In an embodiment, the capacitor structure 16 may include the sidewall dielectric layer 166 disposed on the side surface of the through electrode 164 or the input/output connection wiring 188 as the dielectric layer. By including the sidewall dielectric layer 166 disposed on the side surface of the through electrode 164 or the input/output connection wiring 188 as a dielectric layer as described above, a structure may be simplified and an area of the semiconductor device 10 may be reduced.

The sidewall dielectric layer 166 may have a dielectric constant higher than a dielectric constant of the interlayer insulating layer 132m or at least a portion of the gate dielectric layer 150 (e.g., the tunneling layer 152 or the charge storage layer 154). In some embodiments, the sidewall dielectric layer 166 may have a dielectric constant equal to or higher than a dielectric constant of the blocking layer 156. In some embodiments, the sidewall dielectric layer 166 may have a dielectric constant higher than a dielectric constant of the side insulating layer 184i disposed on the side surface of the gate contact 184 and/or a side insulating layer 168i disposed on a side surface of the voltage application electrode 168.

The sidewall dielectric layer 166 may include any of various insulating materials. For example, the sidewall dielectric layer 166 may include or be formed of a high dielectric constant material having a dielectric constant higher than a dielectric constant of silicon oxide, a ferroelectric material, an antiferroelectric material, or a combination thereof. Since the sidewall dielectric layer 166 includes the high dielectric constant material, the ferroelectric material, the antiferroelectric material, or a combination thereof as described above, capacitance or the like of the capacitor structure 16 may be improved.

For example, the sidewall dielectric layer 166 may include or be formed of at least one of hafnium oxide (HfO), aluminum hafnium oxide (AlHfO), zirconium hafnium oxide (ZrHfO), silicon hafnium oxide (SiHfO), hafnium oxynitride (HfON), silicon hafnium oxynitride (SiHfON), lanthanum oxide (LaO), aluminum lanthanum oxide (AlLaO), zirconium oxide (ZrO), silicon zirconium oxide (SiZrO), zirconium oxynitride (ZrON), silicon zirconium oxynitride (SiZrON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), or lead scandium tantalum oxide (PbScTaO). However, the embodiments are not limited thereto, and the sidewall dielectric layer 166 may include any of various materials. The sidewall dielectric layer 166 may include a single layer or a plurality of layers including different materials.

Since the sidewall dielectric layer 166 includes the material having the dielectric constant high than the dielectric constant of the interlayer insulating layer 132m or at least a portion of the gate dielectric layer 150 as described above, the capacitance or the like of the capacitor structure 16 may be effectively improved.

The sidewall dielectric layer 166 may include a first dielectric portion 166a and a second dielectric portion 166b. The first dielectric portion 166a may be disposed between at least one of the plurality of gate electrodes 130 and the through electrode 164, and may extend in the vertical direction. The second dielectric portion 166b may be disposed between at least one of the plurality of interlayer insulating layers 132m and the through electrode 164, and may extend in the horizontal direction. In a cross-sectional view, the second dielectric portion 166b may be disposed between the plurality of gate electrodes 130, and may protrude outwardly from the first dielectric portion 166a in a plan view. For example, in some embodiments, a plurality of first dielectric portions 166a may be provided with each disposed between the plurality of gate electrodes 130 and the through electrode 164. In some embodiments, a plurality of second dielectric portions 166b may be provided with each disposed between the plurality of interlayer insulating layers 132m and the through electrode 164.

In a process of forming a capacitor through portion where a through structure (e.g., the through electrode 164 and the sidewall dielectric layer 166) of the capacitor structure 16 is disposed, a first through portion extending in a vertical direction may be formed, and thereafter, a portion of the interlayer insulating layer 132m disposed around the first through portion may be removed through the first through portion to form an expanded through portion extending in the horizontal direction. The expanded through portion may correspond to a recess formed in the interlayer insulating layer 132m. The second dielectric portion 166b of the sidewall dielectric layer 166 may be a portion disposed in the expanded through portion.

In an embodiment, since the sidewall dielectric layer 166 includes the first dielectric portion 166a and the second dielectric portion 166b, an area or volume of the sidewall dielectric layer 166 disposed between the first electrode (e.g., the gate electrode 130) and the second electrode (e.g., the through electrode 164) of the capacitor structure 16 may be maximized. In this instance, since the first dielectric portion 166a and the second dielectric portion 166b of the sidewall dielectric layer 166 each include a material with a relatively high dielectric constant, the capacitance of the capacitor structure 16 may stably increase. For example, the first dielectric portion 166a and the second dielectric portion 166b of the sidewall dielectric layer 166 may include the same material as each other and have a dielectric constant higher than a dielectric constant of the interlayer insulating layer 132m or at least a portion of the gate dielectric layer 150.

For example, the capacitor structure 16 may include capacitance of a first capacitor portion CP1 and capacitance of a second capacitor portion CP2. The first capacitor portion CP1 may be formed by the first dielectric portion 166a disposed between the side surface of the gate electrode 130 and the side surface of the through electrode 164. The second capacitor portion CP2 may be formed by the second dielectric portion 166b disposed between an upper surface and/or lower surface of the gate electrode 130 and the side surface of the through electrode 164. Accordingly, the capacitance of the capacitor structure 16 may be effectively improved by the second dielectric portion 166b. Further, by adjusting an area (e.g., a width W2) of the second dielectric portion 166b, the capacitance of the capacitor structure 16 may be easily adjusted.

In an embodiment, a plurality of through electrodes 164 spaced apart from each other in a plan view may be disposed in the first capacitor region CR1. A plurality of sidewall dielectric layers 166 disposed on side surfaces of the plurality of through electrodes 164 may be disposed spaced apart from each other in a plan view. As a result, in a plan view, the sidewall dielectric layer 166 may be disposed in a portion of the first capacitor region CR1, and the interlayer insulating layer 132m may be disposed in another portion of the first capacitor region CR1. According to this, an area where the interlayer insulating layer 132m is removed in the first capacitor region CR1 may be reduced, thereby improving structural stability.

For example, in a plan view, a ratio (W2/W1) of a width W2 of the second dielectric portion 166b to a width W1 of the first dielectric portion 166a may be 1.5 or more (e.g., 2 or more). As a result, the capacitance of the capacitor structure 16 may be greatly improved by the second dielectric portion 166b. However, the embodiments are not limited thereto, and the ratio (W2/W1) of the width W2 of the second dielectric portion 166b to the width W1 of the first dielectric portion 166a may be greater than 1 and may be less than 1.5 (e.g., 2). The width W1 of the first dielectric portion 166a or the width W2 of the second dielectric portion 166b may refer to a minimum width in a portion extending in the horizontal direction around the through electrode 164.

For example, in a plan view, the width W2 of the second dielectric portion 166b may be less than a distance W3 between the second dielectric portions 166b adjacent to each other. According to this, by relatively reducing a size of the second dielectric portion 166b, an area where the interlayer insulating layer 132m is removed may be reduced, thereby improving structural stability. However, the embodiments are not limited thereto. In some embodiments, the width W2 of the second dielectric portion 166b may be equal to or greater than the distance W3 between the second dielectric portions 166b adjacent to each other. According to this, the capacitance of the capacitor structure 16 may be greatly improved by the second dielectric portion 166b. The distance W3 between the second dielectric portions 166b adjacent to each other may refer to a minimum distance between the second dielectric portions 166b adjacent to each other.

In an embodiment, the voltage application electrode 168 may include a first voltage application electrode 1681 disposed on a first side (a left side in FIG. 4) of the first capacitor region CR1 and a second voltage application electrode 1682 disposed on a second side (a right side in FIG. 4) of the first capacitor region CR1. Different voltages may be applied to the first voltage application electrode 1681 and the second voltage application electrode 1682, or the first voltage application electrode 1681 and the second voltage application electrode 1682 may be connected to different voltages. For example, a driving voltage for driving the first electrode (e.g., the gate electrode 130) of the capacitor structure 16 may be applied to the first voltage application electrode 1681, and the second voltage application electrode 1682 may be connected to a ground voltage. According to this, a voltage may be stably applied to the first electrode of the capacitor structure 16. However, the embodiments are not limited thereto, and the voltage application electrode 168 may be formed of the first voltage application electrode 1681 to which the driving voltage is applied, and may not include the second voltage application electrode 1682.

In FIG. 4, it is illustrated as an example that, in the first direction (the X-axis direction in the drawings), a plurality of through electrodes 164 or a plurality of input/output connection wirings 188 are disposed between one first voltage application electrode 1681 and one second voltage application electrode 1682. According to this, the capacitor structure 16 may have a sufficient size to improve capacitance. However, the embodiments are not limited thereto, and the arrangement of the voltage application electrode 168 and the through electrode 164 may be variously modified.

In FIG. 4, it is illustrated as an example that a plurality of through electrodes 164 are disposed inside the first capacitor region CR1, and a plurality of voltage application electrodes 168 are disposed inside each second capacitor region CR2, and the first capacitor region CR1 and the second capacitor region CR2 are provided separately. However, the embodiments are not limited thereto, and the plurality of through electrodes 164 and the plurality of voltage application electrodes 168 may be disposed together in one region. In FIG. 4, it is illustrated as an example that, in the first direction (the X-axis direction in the drawings), the first capacitor region CR1 is disposed in a central region, and the second capacitor regions CR2 are disposed at opposite sides of the first capacitor region CR1, respectively. However, the embodiments are not limited thereto, and the arrangement of the first capacitor region CR1 and/or the second capacitor region CR2 may be variously modified.

When the sidewall dielectric layer 166 includes the second dielectric portion 166b as described above, the gate stacked structure 120 may include a plurality of regions having different stacked structures. For example, the gate stacked structure 120 may include a first stacked region having a first stacked structure S1, and a second stacked region having a second stacked structure S2. In the first stacked region having the first stacked structure S1, a plurality of gate electrodes 130 and a plurality of interlayer insulating layers 132m may be alternately stacked on each other. In the second stacked region having the second stacked structure S2, a plurality of gate electrodes 130 and a plurality of dielectric portions having a dielectric constant higher than a dielectric constant of the interlayer insulating layer 132m may be alternately stacked on each other.

In this instance, the plurality of dielectric portions included in the second stacked structure S2 may be formed of a portion of the sidewall dielectric layer 166 (e.g., a plurality of second dielectric portions 166b of the sidewall dielectric layer 166). For example, the plurality of dielectric portions included in the second stacked structure S2 (e.g., the plurality of second dielectric portions 166b of the sidewall dielectric layer 166) may include the same material (e.g., a material having a dielectric constant higher than a dielectric constant of the interlayer insulating layer 132m) as the sidewall dielectric layer 166 (e.g., the first dielectric portion 166a of the sidewall dielectric layer 166).

In an embodiment, the first region where the memory cell structure is disposed may be the first stacked region having the first stacked structure S1. That is, the memory cell structure may be disposed in the first stacked region. At least a portion of the second region where the capacitor structure 16 is disposed may be the second stacked region having the second stacked structure S2. For example, the first capacitor region CR1 may correspond to the second stacked region having the second stacked structure S2.

In an embodiment, the second region where the capacitor structure 16 is disposed may or may not include the first stacked region having the first stacked structure S1. That is, the capacitor structure 16 may be disposed in a portion including the second stacked region, and the portion where the capacitor structure 16 is disposed may or may not include the first stacked region. For example, the first capacitor region CR1 where the through electrode 164 is disposed may be the second stacked region having the second stacked structure S2, and the second capacitor region CR2 where the voltage application electrode 168 is disposed may be the first stacked region having the first stacked structure S1. For example, the gate stacked structure 120 disposed in the first capacitor region CR1 and the gate stacked structure 120 disposed in the second capacitor region CR2 may have different stacked structures. When the second capacitor region CR2 has the first stacked structure S1 as described above, an area where the interlayer insulating layer 132m is removed may be minimized in the portion where the capacitor structure 16 is disposed, thereby improving stability in a manufacturing process.

In an embodiment, the through electrode 164 or the input/output connection wiring 188 may be formed in a first through portion (e.g., a vertical through portion). The first through portion (e.g., the vertical through portion) may be formed using at least a portion of a high aspect ratio contact (HARC) etching process for forming a channel through portion where a portion of the channel structure CH is disposed. Accordingly, the first through portion of the through electrode 164 or the input/output connection wiring 188 may have a shape corresponding to a shape of the channel through portion. The source contact 186 may be formed in a second through portion formed using at least a portion of the high aspect ratio contact etching process, and the second through portion of the source contact 186 may have a shape corresponding to the shape of the first through portion of the through electrode 164 or the input/output connection wiring 188. In this specification, having a corresponding shape may include a case of having the same or a similar shape and having a difference in size (an area or width) in a plan view.

For example, it is illustrated as an example that the through electrode 164 or the input/output connection wiring 188, and/or the source contact 186 has an inclined side surface and a bent portion at the boundary of the plurality of gate stacked portions 121 and 122 to correspond to the channel structure CH. In some embodiments, when the channel structure CH has an inclined side surface and does not have a bent portion at the boundary of the plurality of gate stacked portions 121 and 122, the through electrode 164 or the input/output connection wiring 188, and/or the source contact 186 may have an inclined side surface and may not have a bent portion at the boundary of the plurality of gate stacked portions 121 and 122.

However, the embodiments are not limited thereto. The first through portion of the through electrode 164 or the input/output connection wiring 188, and/or the second through portion of the source contact 186 may be formed in a process other than the high aspect ratio contact etching process or an etching process for forming the channel through portion, and may have a shape different from a shape of the channel through portion. In some embodiments, the second through portion of the source contact 186 may have a shape different from a shape of the first through portion of the through electrode 164 or the input/output connection wiring 188.

In an embodiment, the voltage application electrode 168 may be formed in a third through portion formed using at least a portion of a process (e.g., partial etching processes using a binary system) for forming a contact through portion where at least a portion of the gate contact 184 is disposed. Accordingly, the third through portion of the voltage application electrode 168 may have a shape corresponding to a shape of the contact through portion.

For example, it is illustrated as an example that the voltage application electrode 168 has an inclined side surface and does not have a bent portion at the boundary of the plurality of gate stacked portions 121 and 122 to correspond to the gate contact 184. In some embodiments, when the gate contact 184 has an inclined side surface and has a bent portion at the boundary of the plurality of gate stacked portions 121 and 122, the voltage application electrode 168 may have an inclined side surface and may have a bent portion at the boundary of the plurality of gate stacked portions 121 and 122.

A side insulating layer 168i may be disposed on a side surface of the voltage application electrode 168, and an end (a lower end in FIG. 2) of the voltage application electrode 168 may be electrically connected to (e.g., in contact with) the gate electrode 130. The voltage application electrode 168 may have a shape corresponding to a shape of the gate contact 184 and/or may include the same material as the gate contact 184, and the side insulating layer 168i disposed on the side surface of the voltage application electrode 168 may have a shape corresponding to a shape of the side insulating layer 184i disposed on the side surface of the gate contact 184 and/or may include the same material as the side insulating layer 184i disposed on the side surface of the gate contact 184.

When an electrical connection structure of the plurality of gate electrodes 130 and the plurality of voltage application electrodes 168 in the second region is same as or similar to an electrical connection structure of the plurality of gate electrodes 130 and the plurality of gate contacts 184 in the first region, the voltage application electrode 168 may be formed using at least a portion of a process of forming the gate contact 184, thereby simplifying a manufacturing process. However, the embodiments are not limited thereto.

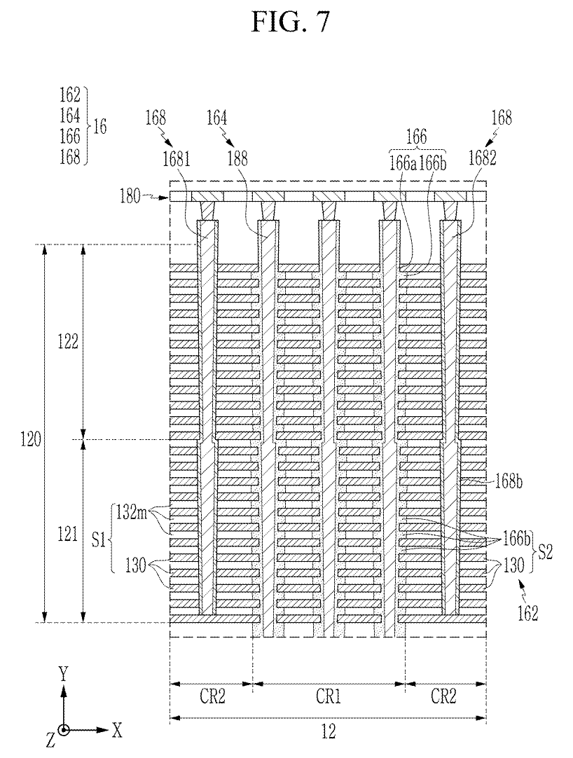

It is illustrated as an example that the third through portion of the voltage application electrode 168 is formed separately from the first through portion of the through electrode 164 or the input/output connection wiring 188, the second through portion of the source contact 186, and/or the channel through portion of the channel structure CH, and has a shape different from a shape of the first through portion of the through electrode 164 or the input/output connection wiring 188, the second through portion of the source contact 186, and/or the channel through portion of the channel structure CH. However, the embodiments are not limited thereto, and the third through portion of the voltage application electrode 168 may be formed together with at least a portion of the first through portion of the through electrode 164 or the input/output connection wiring 188, the second through portion of the source contact 186, and/or the channel through portion of the channel structure CH, or may have a corresponding shape with the first through portion of the through electrode 164 or the input/output connection wiring 188, the second through portion of the source contact 186, and/or the channel through portion of the channel structure CH. This will be described in detail later with reference to FIGS. 7-9.

In an embodiment, a plurality of voltage application electrodes 168 may be provided, and the plurality of voltage application electrodes 168 may be electrically connected and correspond to the plurality of gate electrodes 130, respectively. For example, each of the plurality of voltage application electrodes 168 may be an individual voltage application electrode individually electrically connected to one of the plurality of gate electrodes 130. That is, one or a plurality of voltage application electrodes 168 may be connected to each gate electrode 130, and one voltage application electrode 168 may be an individual voltage application electrode electrically connected to one gate electrode 130. For example, the plurality of voltage application electrodes 168 may have a one-to-one correspondence with the plurality of gate electrodes 130, but the embodiments are not limited thereto.

For example, in some embodiments, a plurality of first voltage application electrodes 1681 may be provided, and the plurality of first voltage application electrodes 1681 may be electrically connected and correspond to the plurality of gate electrodes 130, respectively. For example, each of the plurality of first voltage application electrodes 1681 may be an individual voltage application electrode individually electrically connected to one of the plurality of gate electrodes 130. That is, one or a plurality of first voltage application electrodes 1681 may be connected to each gate electrode 130, and one first voltage application electrode 1681 may be an individual voltage application electrode electrically connected to one gate electrode 130. For example, the plurality of first voltage application electrodes 1681 may have a one-to-one correspondence with the plurality of gate electrodes 130, but the embodiments are not limited thereto.

For example, in some embodiments, a plurality of second voltage application electrodes 1682 may be provided, and the plurality of second voltage application electrodes 1682 may be electrically connected and correspond to the plurality of gate electrodes 130, respectively. For example, each of the plurality of second voltage application electrodes 1682 may be an individual voltage application electrode individually electrically connected to one of the plurality of gate electrodes 130. That is, one or a plurality of second voltage application electrodes 1682 may be connected to each gate electrode 130, and one second voltage application electrode 1682 may be an individual voltage application electrode electrically connected to one gate electrode 130. For example, the plurality of second voltage application electrodes 1682 may have a one-to-one correspondence with the plurality of gate electrodes 130, but the embodiments are not limited thereto.

When the voltage application electrode 168 is the individual voltage application electrode as described above, charge loss may be reduced, and the voltage of the plurality of gate electrodes 130 may be separately controlled and thus the operation of the capacitor structure 16 may be stably performed and a gate electrode 130 having a defect may be easily identified.

In an embodiment, the gate contact 184, the source contact 186, the through electrode 164 or the input/output connection wiring 188, and/or the voltage application electrode 168 may include any of various conductive materials. For example, the gate contact 184, the source contact 186, the through electrode 164 or the input/output connection wiring 188, and/or the voltage application electrode 168 may include or be formed of a metal material, a semiconductor material, metal nitride, or a combination thereof. The metal material may include tungsten (W), titanium (Ti), tantalum (Ta), copper (Cu), aluminum (Al), cobalt (Co), molybdenum (Mo), or ruthenium (Ru), or may include an alloy including at least one of the above materials. The semiconductor material may include polycrystalline silicon. The metal nitride may include titanium nitride (TiN), tantalum nitride (TaN), or the like. However, the embodiments are not limited to the material of the gate contact 184, the source contact 186, the through electrode 164 or the input/output connection wiring 188, and/or the voltage application electrode 168.

At least two of the gate electrode 130, the gate contact 184, the source contact 186, the through electrode 164 or the input/output connection wiring 188, and/or the voltage application electrode 168 may include the same conductive material. In some embodiments, at least two of the gate electrode 130, the gate contact 184, the source contact 186, the through electrode 164 or the input/output connection wiring 188, and/or the voltage application electrode 168 may include different conductive materials.

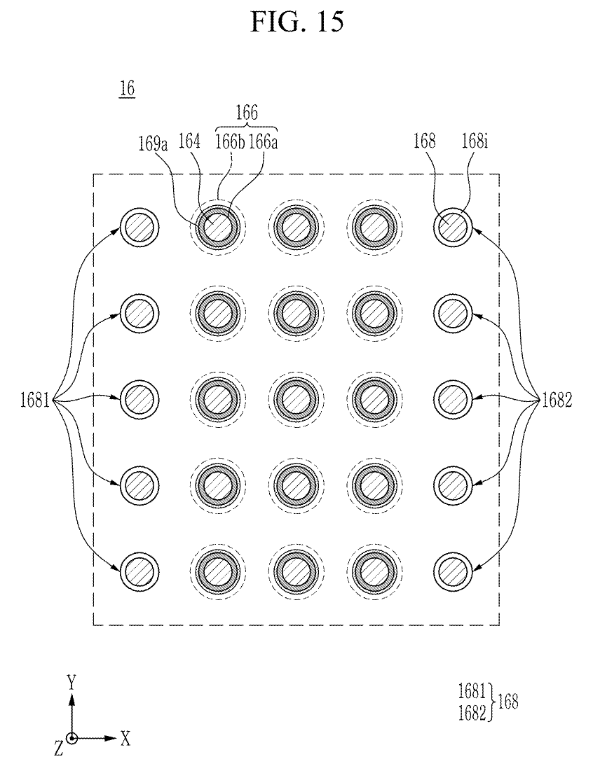

It is described and illustrated as an example that the sidewall dielectric layer 166 and the gate electrode 130 are sequentially disposed on the side surface of the through electrode 164 or the input/output connection wiring 188. However, the embodiments are not limited thereto, and an additional layer may be provided between the through electrode 164 or the input/output connection wiring 188 and the sidewall dielectric layer 166 and/or between the sidewall dielectric layer 166 and the gate electrode 130. Embodiments will be described in detail later with reference to FIGS. 15-17.

A manufacturing method of a semiconductor device 10 according to an embodiment will be briefly described as follows. The manufacturing method of the semiconductor device 10 will be mainly described with respect to a gate stacked structure 120, a channel structure CH, and a capacitor structure 16.

An insulating stacked structure 120s may be formed by alternately stacking a plurality of interlayer insulating layers 132m and a plurality of sacrificial insulating layers 130s in at least a portion of a cell array region 102, a connection region 104, and an outer region 12.

A channel structure CH, a contact through portion, first to third through portions, and an opening for a separation structure, which penetrate the insulating stacked structure 120s, may be formed. The contact through portion may be a through portion where a gate contact 184 is disposed, the first through portion may be a through portion where a through electrode 164 or an input/output connection wiring 188 is disposed, the second through portion may be a through portion where a source contact 186 is disposed, and the third through portion may be a through portion where a voltage application electrode 168 is disposed. The first to third through portions may be referred to as vertical through portions.

For example, the channel structure CH may be formed by forming a channel through portion using a high aspect ratio contact etching process and thereafter forming a channel layer 140, a gate dielectric layer 150, a core insulating layer 142, and/or a channel pad 144 in the channel through portion. The contact through portion and the first to third through portions may be formed by any of various etching processes (e.g., the high aspect ratio contact etching process, partial etching processes using a binary system, or the like). For example, the first through portion and/or the second through portion may be formed by the high aspect ratio contact etching process or the process of forming the channel through portion, and the contact through portion and/or the third through portion may be formed by the partial etching processes using the binary system. An order of the process of forming the channel structure CH, the process of forming the contact through portion, the process of forming the first through portion, the process of forming the second through portion, the process of forming the third through portion, and the process of forming the opening for the separation structure may be variously modified.

Through the opening for the separation structure, the plurality of sacrificial insulating layers 130s disposed in at least a portion of the cell array region 102, the connection region 104, and the outer region 12 may be selectively removed, and the gate electrodes 130 may be formed in portions where the sacrificial insulating layers 130s are removed. That is, a gate stacked structure 120 may be formed by replacing the plurality of sacrificial insulating layers 130s with the gate electrodes 130 through the opening for the separation structure. A separation structure 146 may be formed by filling the opening for the separation structure with a filling material.

A side insulating layer 184i and a gate contact 184 may be formed in the contact through portion.

Through the first through portion (e.g., the vertical through portion), a portion of the interlayer insulating layer 132m disposed around the first through portion may be removed to form an expanded through portion extending in a horizontal direction. A sidewall dielectric layer 166 and a through electrode 164 (e.g., an input/output connection wiring 188) may be sequentially formed in a capacitor through portion including the first through portion and the expanded through portion. As a result, the sidewall dielectric layer 166 may include a first dielectric portion 166a disposed on a side surface of the first through portion and a second dielectric portion 166b disposed in the expanded through portion.

A source contact 186 may be formed in the second through portion.

A side insulating layer 168i and a voltage application electrode 168 may be sequentially formed in the third through portion.

An order of the process of forming the side insulating layer 184i, the process of forming the gate contact 184, the process of forming the sidewall dielectric layer 166, the process of forming the through electrode 164 or the input/output connection wiring 188, the process of forming the source contact 186, the process of forming the side insulating layer 168i, and the process of forming the voltage application electrode 168 may be variously modified. For example, at least a portion of the process of forming the side insulating layer 184i and at least a portion of the process of forming the side insulating layer 168i may be performed together. For example, at least two of at least a portion of the process of forming the gate contact 184, at least a portion of the process of forming the through electrode 164 or the input/output connection wiring 188, at least a portion of the process of forming the source contact 186, and at least a portion of the process of forming the voltage application electrode 168 may be performed together. Other various modified embodiments are possible.

By the manufacturing method described above, a memory cell structure including the gate stacked structure 120 and the channel structure CH may be formed in a first region, and a capacitor structure 16 including a horizontal electrode 162 (e.g., the gate electrode 130), a through electrode 164 (e.g., the input/output connection wiring 188), the sidewall dielectric layer 166, and/or the voltage application electrode 168 may be formed in a second region.

According to an embodiment, the capacitor structure 16 may include an electrode and/or wiring (e.g., the gate electrode 130 and the input/output connection wiring 188) included in the semiconductor device 10 and the sidewall dielectric layer 166 disposed on a side surface of the electrode and/or wiring, thereby achieving a simple structure and large capacitance without requiring an additional area. The sidewall dielectric layer 166 may include a material having a relatively high dielectric constant and may include the first dielectric portion 166a and the second dielectric portion 166b that extends in the horizontal direction from the first dielectric portion 166a, thereby effectively improving the capacitance of the capacitor structure 16. Accordingly, a capacitor provided in the circuit region 200 may be omitted or reduced and thus an area of the semiconductor device 10 may be reduced. As a result, performance and productivity of the semiconductor device 10 may be improved.

In the above description, the semiconductor device 10 may be a NAND flash memory device, and may include the gate stacked structure 120 including the plurality of gate electrodes 130 and the channel structure CH as the memory cell structure.

However, the embodiments are not limited thereto. Therefore, the semiconductor device may include any of various memory devices other than a NAND flash memory device, a three-dimensional semiconductor device (e.g., a three-dimensional memory device), a semiconductor package, or the like. For example, the semiconductor device may include an electrode stacked structure formed by repeatedly forming two layers including different materials as a memory cell structure. In this instance, the electrode stacked structure may include a plurality of interlayer insulating layers and a plurality of electrodes that are alternately stacked on each other. For example, the electrode stacked structure may include a plurality of interlayer insulating layers (e.g., oxide layers) and a plurality of semiconductor material layers (e.g., silicon layers) that are alternately stacked on each other. In this instance, the memory cell structure may include or may not include a channel structure or a through structure that penetrates the electrode stacked structure. A plurality of electrode contacts may be electrically connected to the plurality of electrodes, respectively.

The description of the capacitor structure 16 including the plurality of gate electrodes 130 of the gate stacked structure 120, the through electrode 164 or the input/output connection wiring 188, and the sidewall dielectric layer may be applied to a capacitor structure including the plurality of electrodes of the electrode stacked structure, a through electrode or an input/output connection wiring, and a sidewall dielectric layer. For example, a semiconductor device including the capacitor structure including the plurality of electrodes of the electrode stacked structure, the through electrode or the input/output connection wiring, and the sidewall dielectric layer may be a DRAM or the like. Other various modified embodiments are possible.

Hereinafter, semiconductor devices and manufacturing methods thereof according to embodiments will be described in detail with reference to FIGS. 7-18. To the extent that an element is not described in detail below, it may be understood that the element is at least substantially similar (and/or the same as) to a corresponding element that has been described elsewhere within the present disclosure. A portion which is not described in the above will be described in detail.

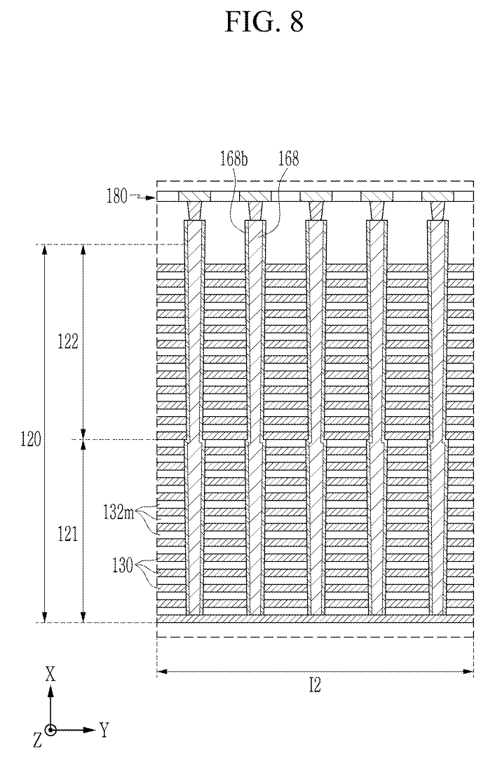

FIG. 7 is a cross-sectional view illustrating a semiconductor device according to an embodiment, and FIG. 8 is another cross-sectional view illustrating the semiconductor device illustrated in FIG. 7. FIG. 7 illustrates a portion corresponding to FIG. 5, and FIG. 8 illustrates a portion corresponding to FIG. 6.

Referring to FIGS. 7 and 8, in an embodiment, a plurality of voltage application electrodes 168 may be provided, and each voltage application electrode 168 may be connected to a plurality of gate electrodes 130 together. For example, each voltage application electrode 168 may be a common voltage application electrode connected to the plurality of gate electrodes 130 together. When the voltage application electrode 168 is a common voltage application electrode as described above, the voltage application electrode 168 may be manufactured by a simple process.

In an embodiment, a side insulating layer may not be provided on a side surface of the voltage application electrode 168. In FIGS. 7 and 8, it is illustrated as an example that a barrier layer 168b is provided on the side surface of the voltage application electrode 168, but the barrier layer 168b may be omitted. The barrier layer 168b may be a layer that does not interfere with an electrical connection between the voltage application electrode 168 and the gate electrode 130, and may include a metal material, a semiconductor material, metal nitride, or a combination thereof.

In an embodiment, the voltage application electrode 168 may be formed in a through portion formed using at least a portion of a high aspect ratio contact etching process for forming a channel through portion or an etching process for forming an input/output connection wiring 188. Accordingly, the voltage application electrode 168 may have a shape corresponding to a shape of the channel structure or the input/output connection wiring 188.

For example, the voltage application electrode 168 may have an inclined side surface and has a bent portion at a boundary of a plurality of gate stacked portions 121 and 122 to correspond to the channel structure or the input/output connection wiring 188. In some embodiments, when the channel structure or the input/output connection wiring 188 has an inclined side surface and does not have the bent portion at the boundary of the plurality of gate stacked portions 121 and 122, the voltage application electrode 168 may have an inclined side surface and may not have the bent portion at the boundary of the plurality of gate stacked portions 121 and 122.

In this instance, a sidewall dielectric layer 166 may be disposed on a side surface of a through electrode 164 such that the through electrode 164 is insulated from the gate electrode 130 while interposing the sidewall dielectric layer 166 therebetween. The sidewall dielectric layer 166 or a side insulating layer may be not disposed on a side surface of the voltage application electrode 168, and the voltage application electrode 168 may be electrically connected to the gate electrode 130. That is, the through electrode 164 may differ from the voltage application electrode 168 in that the through electrode 164 does not include the sidewall dielectric layer 166 or the side insulating layer and is electrically connected to the gate electrode 130.

In FIGS. 7 and 8, it is illustrated as an example that a lower end of the voltage application electrode 168 is disposed on an upper portion of a lowermost gate electrode not to penetrate a second substrate. However, the embodiments are not limited thereto, and any of various modified embodiments are possible. In some embodiments, the voltage application electrode 168 may penetrate the second substrate, like the input/output connection wiring 188. In this instance, an insulating layer that electrically insulates the second substrate and the voltage application electrode 168 may be disposed between the second substrate and the voltage application electrode 168.

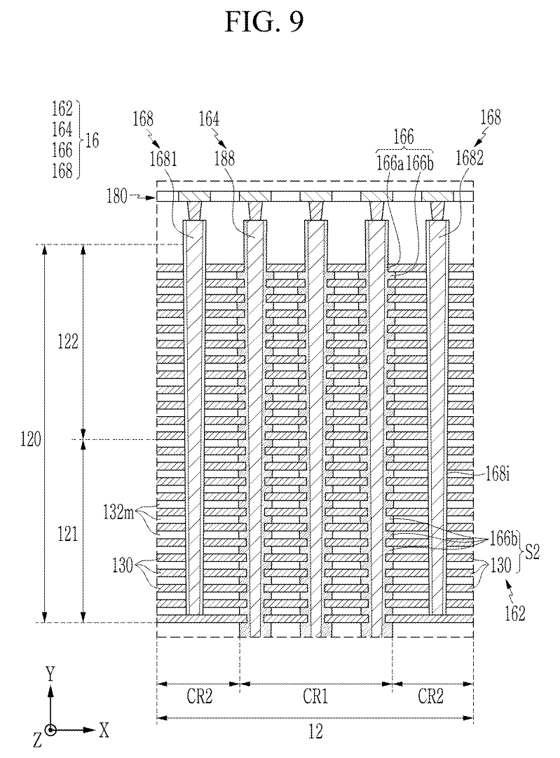

FIG. 9 is a cross-sectional view illustrating a semiconductor device according to an embodiment. FIG. 9 illustrates a portion corresponding to FIG. 5.

Referring to FIG. 9, in an embodiment, a first through portion (e.g., a vertical through portion) of a through electrode 164 or an input/output connection wiring 188 may be formed using at least a portion of a process of forming a contact through portion of a gate contact (e.g., partial etching processes using a binary system).

For example, the through electrode 164 or the input/output connection wiring 188 may have an inclined side surface and does not have a bent portion at a boundary of a plurality of gate stacked portions 121 and 122 to correspond to the gate contact. In some embodiments, when the gate contact may have an inclined side surface and may have a bent portion at the boundary of the plurality of gate stacked portions 121 and 122, the through electrode 164 or the input/output connection wiring 188 may have an inclined side surface and may have a bent portion at the boundary of the plurality of gate stacked portions 121 and 122.

In FIG. 9, it is illustrated as an example that a third through portion of the voltage application electrode 168 is formed using at least a portion of a process of forming a contact through portion (e.g., partial etching processes using a binary system). Accordingly, the third through portion of the voltage application electrode 168 may have a shape corresponding to a shape of the contact through portion. For example, the third through portion of the voltage application electrode 168 may have a shape corresponding to a shape of the first through portion of the through electrode 164 or the input/output connection wiring 188.

However, the embodiments are not limited thereto. The third through portion of the voltage application electrode 168 may have a shape corresponding to a channel through portion as illustrated in FIGS. 7 and 8, and/or may have a different shape from the first through portion of the through electrode 164 or the input/output connection wiring 188.

In FIG. 9, it is illustrated as an example that a sidewall dielectric layer 166 is disposed on a side surface of the through electrode 164, and a side insulating layer 168i having a dielectric constant lower than a dielectric constant of the sidewall dielectric layer 166 is disposed on a side surface of the voltage application electrode 168. In this instance, the side insulating layer 168i disposed on the side surface of the voltage application electrode 168 may be formed of a portion extending in a vertical direction, and may not include a portion extending in a horizontal direction or a portion corresponding to a second dielectric portion of the sidewall dielectric layer 166.

However, the embodiments are not limited thereto. A layer corresponding to the sidewall dielectric layer 166 may be disposed on the side surface of the voltage application electrode 168 instead of the side insulating layer 168i. For example, in a process of forming the sidewall dielectric layer 166 in a capacitor through portion, the sidewall dielectric layer 166 may be formed together in the third through portion. Thereby, a layer corresponding to the sidewall dielectric layer 166 may be disposed on the side surface of the third through portion. In this instance, an extended through portion may be formed through the third through portion in a process of forming an extended through portion through the first through portion, and the sidewall dielectric layer 166 may be formed together in the third through portion and the extended through portion extending from the third through portion in a process of forming the sidewall dielectric layer 166 in the first through portion and the extended through portion extending from the first through portion. Thereby, a layer disposed on the side surface of the voltage application electrode 168 and corresponding to the sidewall dielectric layer 166 may include a portion corresponding to a first dielectric portion of the sidewall dielectric layer 166 and a portion corresponding to a second dielectric portion of the sidewall dielectric layer 166. In some embodiments, the extended through portion may not be formed through the third through portion in the process of forming the extended through portion through the first through portion. Thereby, a layer disposed on the side surface of the voltage application electrode 168 and corresponding to the sidewall dielectric layer 166 may entirely include the portion corresponding to the first dielectric portion of the sidewall dielectric layer 166 and may not include the portion corresponding to the second dielectric portion of the sidewall dielectric layer 166.

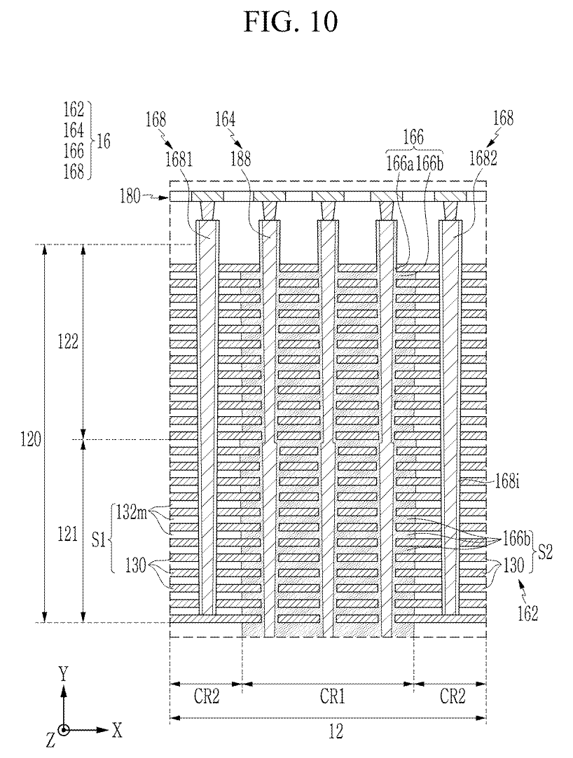

FIG. 10 is a cross-sectional view illustrating a portion of a semiconductor device according to an embodiment. FIG. 10 illustrates a portion corresponding to FIG. 5.

Referring to FIG. 10, in an embodiment, in a first capacitor region CR1, a sidewall dielectric layer 166 (e.g., a second dielectric portion 166b) disposed on a side surface of a plurality of through electrodes 164 may be connected to each other to form an integral structure. That is, in the first capacitor region CR1, a second dielectric portion 166b of a plurality of sidewall dielectric layers 166 disposed on side surfaces of the plurality of through electrodes 164 may be connected to each other in a plan view.

For example, in the first capacitor region CR1, in a portion disposed between gate electrodes 130, the sidewall dielectric layer 166 may be entirely disposed in a plan view. An interlayer insulating layer 132m may not be disposed in the first capacitor region CR1. According to this, in the first capacitor region CR1, the sidewall dielectric layer 166 is entirely disposed between the gate electrodes 130, which may greatly improve capacitance of a capacitor structure 16. However, the embodiments are not limited thereto. Even when the sidewall dielectric layer 166 (e.g., the second dielectric portion 166b) is connected to each other to form an integral structure in the first capacitor region CR1, the interlayer insulating layer 132m may remain in some regions in the first capacitor region CR1.

In FIG. 10, it is illustrated as an example that the first capacitor region CR1 has a second stacked structure S2 and a second capacitor region CR2 has a first stacked structure S1. However, the embodiments are not limited thereto. In some embodiments, the second dielectric portion 166b of the sidewall dielectric layer 166 may be disposed in at least a portion of the second capacitor region CR2 or around a voltage application electrode 168, and at least a portion of the second capacitor region CR2 or a periphery of the voltage application electrode 168 may have the second stacked structure S2.

In FIG. 10, it is illustrated as an example that the through electrode 164 and the voltage application electrode 168 of the capacitor structure 16 have a structure described with reference to FIG. 5. However, the embodiments are not limited thereto. In some embodiments, the through electrode 164 and the voltage application electrode 168 of the capacitor structure 16 may have a structure described with reference to FIGS. 7 or 9. Other various modified embodiments are possible.

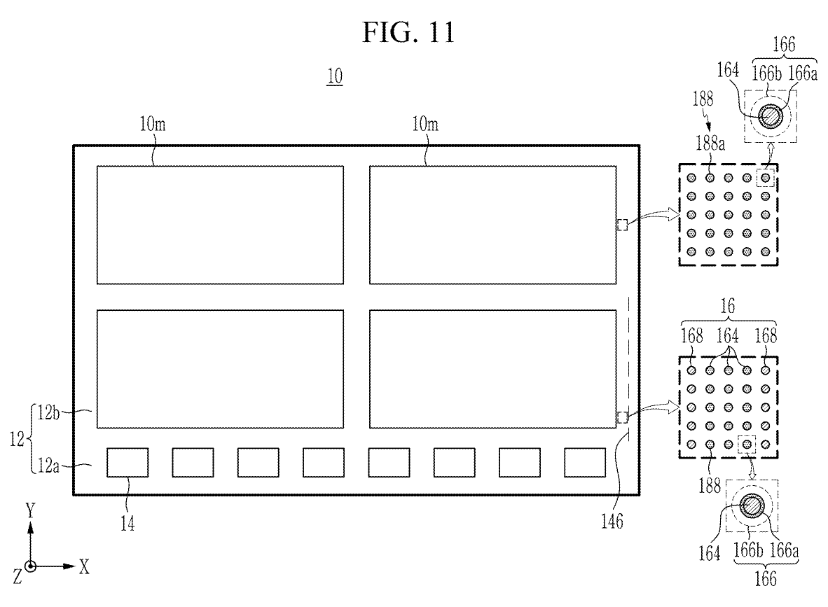

FIG. 11 is a plan view illustrating a semiconductor device according to an embodiment. FIG. 11 illustrates a portion corresponding to FIG. 1. For a clear understanding, in FIG. 11, a separation structure 146 for forming a capacitor structure 16 in an outer region 12 is illustrated as a dotted line.

Referring to FIG. 11, in an embodiment, a separation structure 146 and a capacitor structure 16 may be disposed in a portion of an outer region 12, and the capacitor structure 16 may be not disposed in another portion of the outer region 12.

In an embodiment, the capacitor structure 16 may include a first electrode, a horizontal electrode, or a gate electrode that extends in a horizontal direction, a second electrode or a through electrode 164 that extends in a direction crossing the horizontal direction (e.g., a vertical direction or a Z-axis direction in the drawings), and a sidewall dielectric layer 166 that is disposed between the first electrode and the second electrode on a side surface of the first electrode. The capacitor structure 16 may include a voltage application electrode 168 that extends in the direction crossing the horizontal direction (e.g., the vertical direction or the Z-axis direction in the drawings) to apply a voltage to the first electrode. The second electrode or the through electrode 164 may be formed of an input/output connection wiring 188, and the sidewall dielectric layer 166 disposed on the side surface of the second electrode or the through electrode 164 may have a dielectric constant higher than a dielectric constant of an interlayer insulating layer or at least a portion of a gate dielectric layer, and may include a first dielectric portion 166a and a second dielectric portion 166b.

For example, on a side surface of the input/output connection wiring 188 (e.g., an additional input/output connection wiring 188a) disposed in a portion where the capacitor structure 16 is not disposed, the sidewall dielectric layer 166 having a dielectric constant higher than a dielectric constant of the interlayer insulating layer or at least a portion of the gate dielectric layer may be disposed, like the input/output connection wiring 188 included in the capacitor structure 16. In some embodiments, the sidewall dielectric layer 166 disposed on the side surface of the additional input/output connection wiring 188a may include a first dielectric portion 166a and a second dielectric portion 166b. In some embodiments, the sidewall dielectric layer 166 disposed on the side surface of the additional input/output connection wiring 188a may include the first dielectric portion 166a without the second dielectric portion 166b.

In some embodiments, an insulating layer having a dielectric constant lower than a dielectric constant of the sidewall dielectric layer 166 may be disposed on the side surface of the additional input/output connection wiring 188a. In some embodiments, a gate stacked structure may not be disposed and an insulating stacked structure or a cell insulating layer may be disposed in a portion where the additional input/output connection wiring 188a is disposed, and the additional input/output connection wiring 188a may penetrate the insulating stacked structure or the cell insulating layer. An insulating layer may be disposed or may not be disposed on a side surface of the additional input/output connection wiring 188a that penetrates the insulating stacked structure or the cell insulating layer.

FIG. 12 is a plan view illustrating a semiconductor device according to an embodiment. FIG. 12 illustrates a portion corresponding to FIG. 1.

Referring to FIG. 12, in an embodiment, each memory region 10m may include a cell array region 102, a connection region 104, and a dummy region 106. The dummy region 106 may be a region other than the cell array region 102 and the connection region 104, and an insulating stacked structure may be disposed in at least a portion of the dummy region 106.

In an embodiment, a capacitor structure 16 may be disposed inside the memory region 10m. For example, the capacitor structure 16 may be disposed in at least a portion of the dummy region 106 other than the cell array region 102 and the connection region 104 or a region where an insulating stacked structure is disposed. For example, a separation structure 146 for forming the capacitor structure 16 may be disposed in a portion of the dummy region 106, and the capacitor structure 16 may be disposed at a periphery of the separation structure 146. In some embodiments, the capacitor structure 16 may be disposed in a portion of the cell array region 102 and/or the connection region 104. As described above, the capacitor structure 16 may be freely disposed in any of various regions of a semiconductor device 10.

In FIG. 12, it is illustrated that, in a first direction (an X-axis direction in the drawings), each memory region 10m is provided with a plurality of cell array regions 102, connection regions 104 are disposed at opposite sides of each cell array region 102, and a dummy region 106 is disposed at one side (a lower portion in FIG. 12) of the cell array region 102 and the connection region 104. However, the embodiments are not limited thereto. In some embodiments, in the first direction, one cell array region 102 may be provided in each memory region 10m, or the connection region 104 may be disposed at one side of each cell array region 102. Other various modified embodiments are possible.

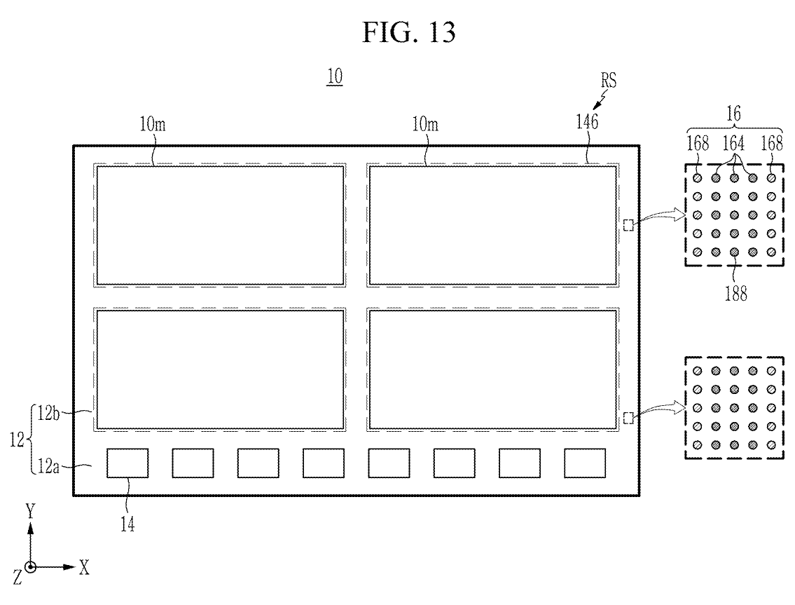

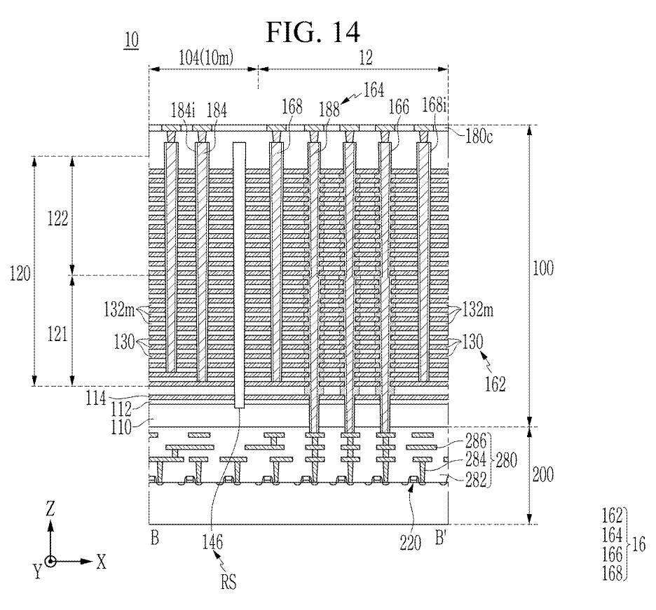

FIG. 13 is a plan view illustrating a semiconductor device according to an embodiment, and FIG. 14 is a cross-sectional view illustrating a portion of the semiconductor device illustrated in FIG. 13. FIG. 13 illustrates a portion corresponding to FIG. 1, and FIG. 14 illustrates a portion corresponding to a right portion of FIG. 2.

Referring to FIGS. 13 and 14, in an embodiment, a regional separation portion RS may be formed of a separation structure 146 disposed between a first region (e.g., a cell array region 102 and/or a connection region 104) and a second region (e.g., an outer region 12). For example, the regional separation portion RS may be formed of the separation structure 146 including an insulating material (e.g., an insulating separation structure).

In an embodiment, by using the separation structure 146 disposed between the first region and the second region as the regional separation portion RS, a gate electrode 130 in the first region and a gate electrode 130 in the second region may be electrically insulated without additionally forming a regional separation portion. Further, a sacrificial insulating layer in the second region may be replaced with the gate electrode 130 by using the separation structure 146, which is the regional separation portion RS that separates the first region and the second region. Thereby, a structure and manufacturing process may be simplified.

In FIG. 13, it is illustrated as an example that the separation structure 146 disposed in the outer region 12 has a shape that extends along an edge of a memory region 10m, and has a frame shape that surrounds one memory region 10m when viewed based on one memory region 10m. Accordingly, when viewed based on one memory region 10m, a gate stacked structure 120 disposed in the outer region 12 may have a shape that entirely surrounds the memory region 10m. According to this, the sacrificial insulating layer of an insulating stacked structure disposed in the outer region 12 may be stably replaced with the gate electrode 130 of the gate stacked structure 120, and the gate stacked structure 120 may be stably formed in the outer region 12. Further, by increasing an area of the gate stacked structure 120 in the outer region 12, a region where the capacitor structure 16 is disposed may increase.

However, the embodiments are not limited thereto, and the shape, position, and arrangement of the separation structure 146 disposed in the outer region 12, and the position and arrangement of the gate stacked structure 120, or the like may be variously modified. For example, as illustrated in FIG. 11, the separation structure 146 and the capacitor structure 16 may be disposed in a portion of the outer region 12, and the capacitor structure 16 may not be disposed in another portion of the outer region 12. For example, as illustrated in FIG. 12, the capacitor structure 16 may be disposed inside the memory region 10m. Other various modified embodiments are possible.

FIG. 15 is a plan view illustrating a semiconductor device according to an embodiment. FIG. 15 illustrates a portion corresponding to FIG. 4.

Referring to FIG. 15, in an embodiment, a first interfacial layer 169a may be disposed between a sidewall dielectric layer 166 and a gate stacked structure (e.g., a gate electrode and an interlayer insulating layer). The first interfacial layer 169a may improve an interface property or a bonding property between the sidewall dielectric layer 166 and the gate electrode. The first interfacial layer 169a may include a portion disposed on an outer surface of a first dielectric portion 166a of the sidewall dielectric layer 166 and a portion disposed on an outer surface of a second dielectric portion 166b of the sidewall dielectric layer 166. A capacitor structure 16 having the first interfacial layer 169a may be formed by sequentially forming the first interfacial layer 169a, the sidewall dielectric layer 166, and a through electrode 164 (e.g., an input/output connection wiring) in a capacitor through portion.

The first interfacial layer 169a may include any of various materials (e.g., an insulating material). For example, a dielectric constant of the first interfacial layer 169a may be lower than a dielectric constant of the sidewall dielectric layer 166. For example, the first interfacial layer 169a may include or be formed of silicon oxide, silicon nitride, silicon oxynitride, a low dielectric constant material having a dielectric constant lower than a dielectric constant of silicon oxide, or a combination thereof. However, the embodiments are not limited thereto, and the first interfacial layer 169a may include a material having a dielectric constant higher than a dielectric constant of the sidewall dielectric layer 166.

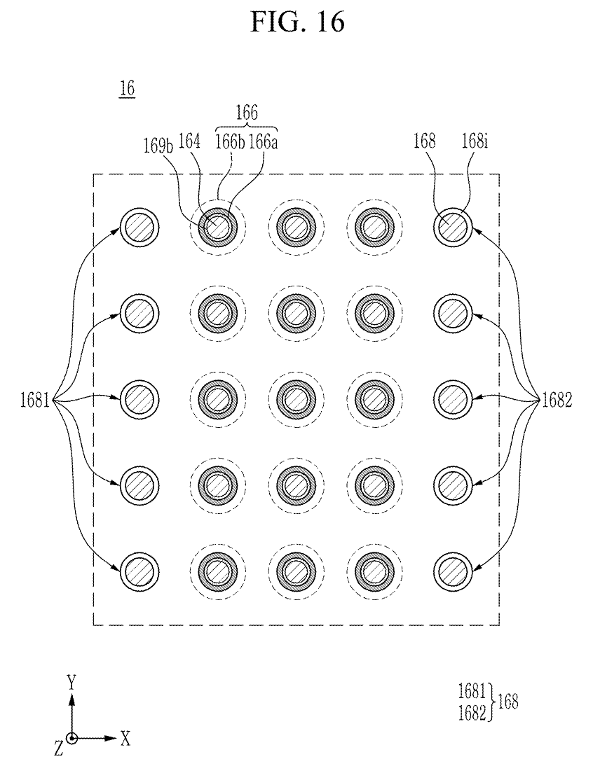

FIG. 16 is a plan view illustrating a semiconductor device according to an embodiment. FIG. 16 illustrates a portion corresponding to FIG. 4.

Referring to FIG. 16, in an embodiment, a second interfacial layer 169b may be disposed between a through electrode 164 and a sidewall dielectric layer 166. The second interfacial layer 169b may improve an interface property or a bonding property between the through electrode 164 and the sidewall dielectric layer 166. The second interfacial layer 169b may include a portion extending in a vertical direction along a side surface of the through electrode 164. A capacitor structure 16 having the second interfacial layer 169b may be formed by sequentially forming the sidewall dielectric layer 166, the second interfacial layer 169b, and the through electrode 164 (e.g., an input/output connection wiring) in a capacitor through portion.

The second interfacial layer 169b may include any of various materials (e.g., an insulating material or a conductive material). For example, when the second interfacial layer 169b includes an insulating material, a dielectric constant of the second interfacial layer 169b may be lower than a dielectric constant of the sidewall dielectric layer 166. For example, the second interfacial layer 169b may include or be formed of silicon oxide, silicon nitride, silicon oxynitride, a low dielectric constant material having a dielectric constant lower than a dielectric constant of silicon oxide, or a combination thereof. However, the embodiments are not limited thereto, and the second interfacial layer 169b may include a material having a dielectric constant higher than a dielectric constant of the sidewall dielectric layer 166. For example, when the second interfacial layer 169b includes a conductive material, the second interfacial layer 169b may include or be formed of a metal material, a semiconductor material, metal nitride, or a combination thereof. The metal material may include tungsten (W), titanium (Ti), tantalum (Ta), copper (Cu), aluminum (Al), cobalt (Co), molybdenum (Mo), or ruthenium (Ru), or may include an alloy including at least one of the above materials. The semiconductor material may include polycrystalline silicon. The metal nitride may include tungsten nitride (WN), titanium nitride (TiN), tantalum nitride (TaN), or the like

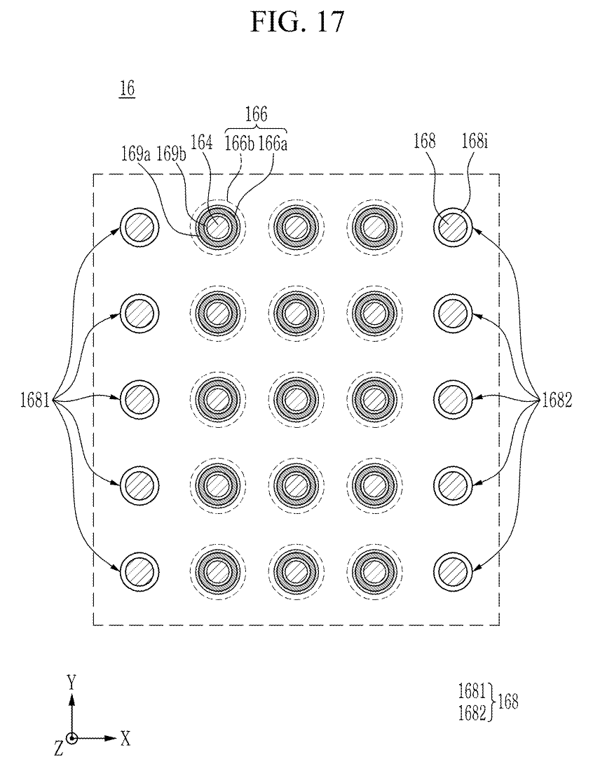

FIG. 17 is a plan view illustrating a semiconductor device according to an embodiment. FIG. 17 illustrates a portion corresponding to FIG. 4.

Referring to FIG. 17, in an embodiment, a first interfacial layer 169a may be disposed between a sidewall dielectric layer 166 and a gate stacked structure (e.g., a gate electrode and an interlayer insulating layer), and a second interfacial layer 169b may be disposed between a through electrode 164 and the sidewall dielectric layer 166. By including the first interfacial layer 169a and the second interfacial layer 169b, an interface property or a bonding property between the sidewall dielectric layer 166 and the gate electrode and between the through electrode 164 and the sidewall dielectric layer 166 may be improved. The description of the first interfacial layer 169a with reference to FIG. 15 may be applied to the first interfacial layer 169a, and the description of the second interfacial layer 169b with reference to FIG. 16 may be applied to the second interfacial layer 169b.

A capacitor structure 16 having the first interfacial layer 169a and the second interfacial layer 169b may be formed by sequentially forming the first interfacial layer 169a, the sidewall dielectric layer 166, the second interfacial layer 169b, and the through electrode 164 (e.g., an input/output connection wiring) in a capacitor through portion.

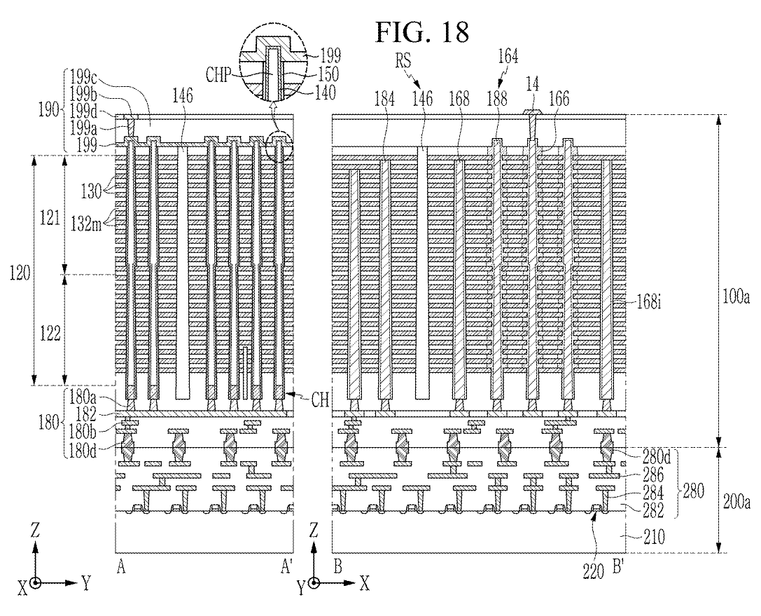

FIG. 18 is a partial cross-sectional view schematically illustrating a semiconductor device according to an embodiment.

Referring to FIG. 18, a semiconductor device according to an embodiment may be a bonding structure. For example, the semiconductor device 10 may be formed by forming a lower chip including a circuit region 200a in which a peripheral circuit structure is provided on a first substrate 210, forming an upper chip including a cell region 100a in which a memory cell structure is provided on a preliminary substrate, and bonding the lower chip and the upper chip. For example, a chip-to-chip (C2C) bonding process, a chip-to-wafer bonding process, or a wafer-to-wafer bonding process may be used for a bonding process for bonding the cell region 100a and the circuit region 200a.

The circuit region 200a may include a first substrate 210, a circuit element 220, and a circuit wiring portion 280. The circuit wiring portion 280 may include an insulating layer 282, a contact via 284, a wiring layer 286, and a bonding structure 280d disposed on a surface facing the cell region 100a. A bonding insulating layer may be disposed in a region other than the bonding structure 280d on a bonding surface of the circuit region 200a facing the cell region 100a.

The cell region 100a may include a gate stacked structure 120, a channel structure CH, a cell wiring portion 180, and an additional cell wiring portion 190.

The cell wiring portion 180 may include a portion adjacent to the circuit region 200a. The cell wiring portion 180 may include a bit line 182, a gate contact 184, an input/output connection wiring 188, a contact via 180a, a connection wiring 180b, and a bonding structure 180d disposed on a surface facing the circuit region 200a. The additional cell wiring portion 190 may be disposed on a surface opposite to the circuit region 200a. The additional cell wiring portion 190 may include a horizontal conductive layer 199, a through-via 199a penetrating an insulating layer 199c and electrically connected to the horizontal conductive layer 199, and a connection wiring 199b electrically connected to the through-via 199a. For a clear understanding and simple illustration, it is illustrated as an example that the connection wiring 199b of the additional cell wiring portion 190 is formed of a single wiring layer, and an additional insulating layer 199d is disposed in a portion other than the single wiring layer. However, the embodiments are not limited thereto. Therefore, the connection wiring 199b of the additional cell wiring portion 190 may include a plurality of wiring layers and may further include a contact via.

In an embodiment, the gate stacked structure 120 may be sequentially stacked below the additional cell wiring portion 190 in the drawing, and may have a vertically reversed structure in which the gate stacked structure 120 illustrated in FIG. 2 is vertically reversed. The channel structure CH penetrating the gate stacked structure 120 may have a vertically reversed structure in which the channel structure CH illustrated in FIG. 3 is vertically reversed. Accordingly, the channel structure CH may have an inclined side surface such that a width of the channel structure decreases far away from the circuit region 200a in a cross-sectional view. A channel pad and the bit line 182 disposed on the gate stacked structure 120 may be disposed adjacent to the circuit region 200a.

For example, the bonding structure 280d of the circuit region 200a and/or the bonding structure 180d of the cell region 100a may include or be formed of aluminum, copper, tungsten, or an alloy including the same. For example, the bonding structure 280d of the circuit region 200a and the bonding structure 180d of the cell region 100a may include copper, and the cell region 100a and the circuit region 200a may be bonded (e.g., directly contacted and bonded) by copper-to-copper bonding.

In an embodiment, the channel structure CH may include a protruding portion CHP that protrudes from a surface of the gate stacked structure 120 opposite to the circuit region 200a. A gate dielectric layer 150 is not provided in the protruding portion CHP, and a channel layer 140 disposed in the protruding portion CHP may be exposed to an outside of the gate stacked structure 120. The horizontal conductive layer 199 may be electrically connected to the channel layer 140 in the protruding portion CHP. However, the embodiments are not limited thereto, and horizontal conductive layers 112 and 114 illustrated in FIG. 2 may be included. Other various modified embodiments are possible.

A semiconductor device according to an embodiment may include an input/output pad 14 and an input/output connection wiring 188 electrically connected to the input/output pad 14. The input/output connection wiring 188 may be electrically connected to a portion of the bonding structure 180d of the cell region 100a. For example, the input/output pad 14 may be disposed on the additional insulating layer 199d, and may be electrically connected to the input/output connection wiring 188 through the through-via 199a. In some embodiments, a separate input/output pad may be included in the circuit region 200a.

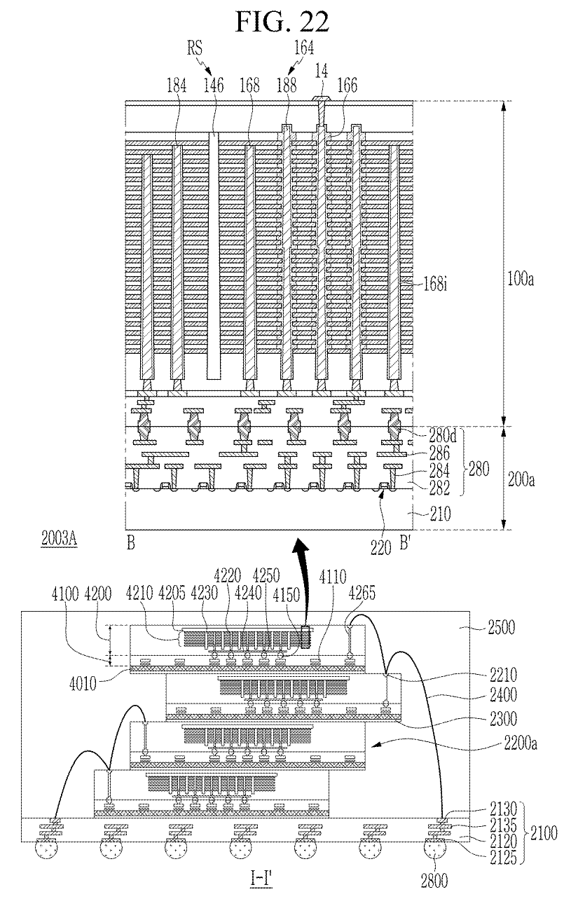

For example, the circuit region 200a and the cell region 100a may correspond to a first structure 1100F and a second structure 1100S of a semiconductor device 1100 included in an electronic system 1000 illustrated in FIG. 19, respectively. For example, the circuit region 200a and the cell region 100a may be regions including a first structure 4100 and a second structure 4200 of a semiconductor chip 2200a illustrated in FIG. 22, respectively.

In FIG. 18, it is illustrated as an example that a regional separation portion RS is a separation structure 146, as illustrated in FIGS. 13 and 14. However, the embodiments are not limited thereto, and the regional separation portion RS may be formed of an insulating stacked structure, as illustrated in FIG. 2. Other various modified embodiments are possible.

In FIG. 18, it is illustrated as an example that a side insulating layer 168i is disposed on a side surface of a voltage application electrode 168, and an end (upper end in FIG. 18) of the voltage application electrode 168 is electrically connected to a gate electrode 130, as illustrated in FIG. 2. That is, the voltage application electrode 168 may be an individual voltage application electrode. However, the embodiments are not limited thereto.

In some embodiments, as illustrated in FIGS. 7 and 8, the voltage application electrode 168 may be a common voltage application electrode that is electrically connected to a plurality of gate electrodes 130 together.

In some embodiments, the voltage application electrode 168 may penetrate all of the plurality of gate electrodes 130, like the input/output connection wiring 188. For example, a through electrode 164 may be formed of a portion of a plurality of input/output connection wirings 188, and the voltage application electrode 168 may be formed of another portion of the plurality of input/output connection wirings 188. A side insulating layer 168i may be disposed on a side surface of the voltage application electrode 168, or a sidewall dielectric layer having a dielectric constant higher than a dielectric constant of an interlayer insulating layer or at least a portion of a gate dielectric layer may be disposed instead of the side insulating layer 168i. The sidewall dielectric layer disposed on the side surface of the voltage application electrode 168 may include a portion corresponding to a first dielectric portion and a portion corresponding to a second dielectric portion, or may include a portion corresponding to the first dielectric portion without a portion corresponding to the second dielectric portion.

An example of an electronic system including the semiconductor device as described above will be described in detail as follows.

FIG. 19 schematically illustrates an electronic system including a semiconductor device according to an embodiment.

Referring to FIG. 19, an electronic system 1000 according to an embodiment may include a semiconductor device 1100 and a controller 1200 that is electrically connected to the semiconductor device 1100. The electronic system 1000 may be a storage device that includes one or a plurality of semiconductor devices 1100 or an electronic device that includes the storage device. For example, the electronic system 1000 may be a solid-state drive (SSD) device, a universal serial bus (USB), a computing system, a medical device, or a communication device that includes one or a plurality of semiconductor devices 1100.

The semiconductor device 1100 may be a non-volatile memory device, and for example, may be a NAND flash memory device described with reference to FIGS. 1-18. The semiconductor device 1100 may include a first structure 1100F and a second structure 1100S that is disposed on the first structure 1100F. In an embodiment, the first structure 1100F may be next to the second structure 1100S. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 that are adjacent to the common source line CSL, upper transistors UT1 and UT2 that are adjacent to the bit line BL, and a plurality of memory cell transistors MCT between the lower transistors LT1 and LT2 and the upper transistors UT1 and UT2. A number of the lower transistors LT1 and LT2 and a number of the upper transistors UT1 and UT2 may be variously modified according to an embodiment.

In an embodiment, the lower transistor LT1 or LT2 may include a ground selection transistor, and the upper transistor UT1 or UT2 may include a string selection transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 that extends to the second structure 1100S within the first structure 1100F. The bit line BL may be electrically connected to the page buffer 1120 through a second connection wiring 1125 that extends to the second structure 1100S within the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through an input/output connection wiring 1135 that extends to the second structure 1100S within the first structure 1100F.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or the like may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

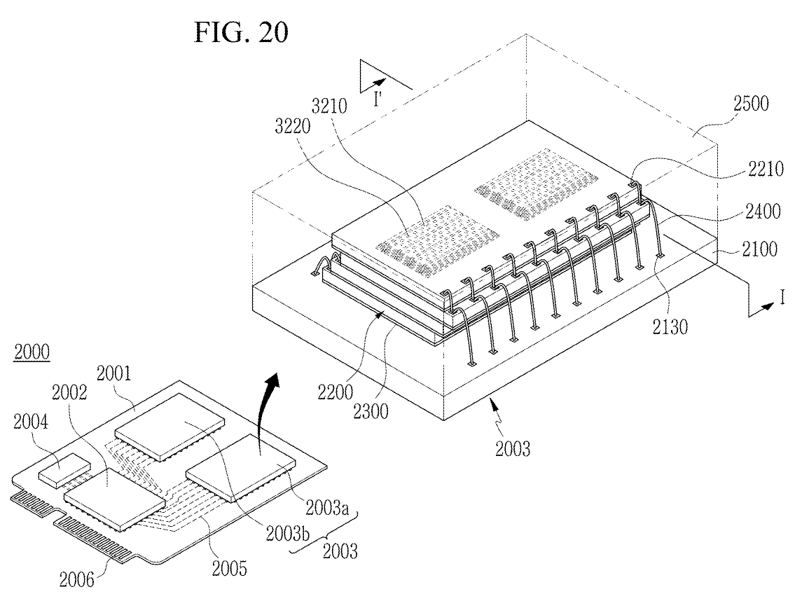

FIG. 20 is a perspective view schematically illustrating an electronic system including a semiconductor device according to an embodiment.

Referring to FIG. 20, an electronic system 2000 according to an embodiment may include a main substrate 2001, a controller 2002 that is mounted on the main substrate 2001, one or more semiconductor packages 2003, and a DRAM 2004. The semiconductor package 2003 and the DRAM 2004 may be connected to the controller 2002 through a wiring pattern 2005 that is provided on the main substrate 2001.

The main substrate 2001 may include a connector 2006 that includes a plurality of pins coupled to the external host. A number and arrangement of the plurality of pins in the connector 2006 may vary depending on a communication interface between the electronic system 2000 and the external host. In an embodiment, the electronic system 2000 may communicate with the external host according to any one of interfaces such as a universal serial bus (USB), a peripheral component interconnect express (PCI-Express), a serial advanced technology attachment (SATA), or an M-Phy for a universal flash storage (UFS). In an embodiment, the electronic system 2000 may operate by power that is supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating or buffering a speed difference between the semiconductor package 2003, which is a data storage space, and the external host. The DRAM 2004 that is included in the electronic system 2000 may also be a kind of cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b that are spaced apart from each other. Each of the first and second semiconductor packages 2003a and 2003b may a semiconductor package including a plurality of semiconductor devices 2200. Each of the first and second semiconductor packages 2003a and 2003b may include a package substrate 2100, the semiconductor device 2200 that is disposed on the package substrate 2100, an adhesive layer 2300 at a lower surface of each semiconductor device 2200, a connection structure 2400 that electrically connects the semiconductor device 2200 and the package substrate 2100, and a molding layer 2500 that covers the semiconductor device 2200 and the connection structure 2400 on the package substrate 2100.

The package substrate 2100 may be a printed circuit board that includes a package upper pad 2130. Each semiconductor device 2200 may include an input/output pad 2210. The input/output pad 2210 may correspond to an input/output pad 1101 of FIG. 19. Each semiconductor device 2200 may include a gate stacked structure 3210 and a channel structure 3220. The semiconductor device 2200 may include a semiconductor device described with reference to FIGS. 1-18.

In an embodiment, the connection structure 2400 may be a bonding wire that electrically connects the input/output pad 2210 and the package upper pad 2130. Accordingly, in each of the first and second semiconductor packages 2003a and 2003b, the semiconductor devices 2200 may be electrically connected to each other using a bonding wire type, and the semiconductor device 2200 may be electrically connected to the package upper pad 2130 of the package substrate 2100. In some embodiments, in each of the first and second semiconductor packages 2003a and 2003b, the semiconductor devices 2200 may be electrically connected to each other by a connection structure that includes a through silicon via (TSV) instead of the connection structure 2400 of the bonding wire type.

In an embodiment, the controller 2002 and the semiconductor device 2200 may be included in one package. For example, the controller 2002 and the semiconductor device 2200 may be mounted on a separate interposer substrate that is different from the main substrate 2001, and the controller 2002 and the semiconductor device 2200 may be connected to each other by a wiring of the interposer substrate.

FIGS. 21 and 22 are cross-sectional views schematically illustrating semiconductor packages according to embodiments, respectively. FIGS. 21 and 22 respectively illustrate embodiments of the semiconductor package 2003 of FIG. 20, and conceptually illustrate a region obtained by cutting the semiconductor package 2003 of FIG. 20 along a line I-I’.

Referring to FIG. 21, in a semiconductor package 2003, a package substrate 2100 may be a printed circuit board. The package substrate 2100 may include a package substrate body portion 2120, a package upper pad 2130 that is disposed at an upper surface of the package substrate body portion 2120, a package lower pad 2125 that is disposed at a lower surface of the package substrate body portion 2120 or is exposed through the lower surface of the package substrate body portion 2120, and an internal wiring 2135 that electrically connects the package upper pad 2130 and the package lower pad 2125 inside the package substrate body portion 2120. The package upper pad 2130 may be electrically connected to the connection structure 2400. The package lower pad 2125 may be connected to a wiring pattern 2005 of a main substrate 2001 of an electronic system 2000, illustrated in FIG. 20, through a conductive connection portion 2600.

The semiconductor device 2200 may include a semiconductor substrate 3010, and a first structure 3100 and a second structure 3200 sequentially stacked on the semiconductor substrate 3010. The first structure 3100 may include a peripheral circuit region including a peripheral wiring 3110. The second structure 3200 may include a common source line 3205, a gate stacked structure 3210 on the common source line 3205, a channel structure 3220 and a separation structure 3230 passing through the gate stacked structure 3210, a bit line 3240 electrically connected to the channel structure 3220, and a gate connection wiring electrically connected to a word line WL (refer to FIG. 19) of the gate stacked structure 3210.

In a semiconductor chip 2200 or a semiconductor device according to an embodiment, a capacitor structure may include an electrode and/or wiring included in the semiconductor device and a sidewall dielectric layer disposed on a side surface of the electrode and/or wiring, and thus, may achieve a simple structure and large capacitance without requiring an additional area. Thereby, performance and productivity of the semiconductor chip 2200 or the semiconductor device may be improved.

Each of the semiconductor devices 2200 may include a through wiring 3245 that is electrically connected to a peripheral wiring 3110 of the first structure 3100 and extends into the second structure 3200. The through wiring 3245 may pass through the gate stacked structure 3210, and may be further provided at an outside of the gate stacked structure 3210. Each semiconductor device 2200 may further include an input/output connection wiring 3265 electrically connected to the peripheral wiring 3110 of the first structure 3100 and extending into the second structure 3200, and an input/output pad 2210 electrically connected to the input/output connection wiring 3265.

In an embodiment, in the semiconductor package 2003, a plurality of semiconductor devices 2200 may be electrically connected to each other by a connection structure 2400 having a bonding wire type. In some embodiments, the plurality of semiconductor devices 2200 or a plurality of portions constituting the plurality of semiconductor devices 2200 may be electrically connected by a connection structure including a through electrode (e.g., a through silicon via (TSV)).

Referring to FIG. 22, in a semiconductor package 2003A, each semiconductor device 2200a may include a semiconductor substrate 4010, a first structure 4100 on the semiconductor substrate 4010, and a second structure 4200 disposed on the first structure 4100 and bonded to the first structure 4100 by a wafer bonding type.

The first structure 4100 may include a peripheral circuit region that includes a peripheral wiring 4110 and a first bonding structure 4150. The second structure 4200 may include a common source line 4205, a gate stacked structure 4210 between the common source line 4205 and the first structure 4100, a channel structure 4220 and a separation structure 4230 that pass through the gate stacked structure 4210, and a second bonding structure 4250 that is electrically connected to the channel structure 4220 and a word line WL (refer to FIG. 19) of the gate stacked structure 4210. For example, the second bonding structure 4250 may be electrically connected to the channel structure 4220 and the word line WL through a bit line 4240 that is electrically connected to the channel structure 4220 and a gate connection wiring that is electrically connected to the word line WL. The first bonding structure 4150 of the first structure 4100 and the second bonding structure 4250 of the second structure 4200 may be in contact with and bonded to each other. For example, portions of the first bonding structure 4150 and the second bonding structure 4250 where the first bonding structure 4150 and the second bonding structure 4250 are bonded may include copper (Cu).

In a semiconductor chip 2200a or a semiconductor device according to an embodiment, a capacitor structure may include an electrode and/or wiring included in the semiconductor device and a sidewall dielectric layer disposed on a side surface of the electrode and/or wiring, and thus, may achieve a simple structure and large capacitance without requiring an additional area. Thereby, performance and productivity of the semiconductor chip 2200a or the semiconductor device may be improved.

Each of the semiconductor devices 2200a may further include an input/output pad 2210 and an input/output connection wiring 4265 that is disposed at a lower portion of the input/output pad 2210. The input/output connection wiring 4265 may be electrically connected to a part of the second bonding structures 4250.

In an embodiment, in the semiconductor package 2003A, a plurality of semiconductor devices 2200a may be electrically connected to each other by a connection structure 2400 having a bonding wire type. In some embodiments, a plurality of semiconductor devices 2200a or a plurality of portions constituting the plurality of semiconductor devices 2200 may be electrically connected to each other by a connection structure including a through electrode (e.g., a through silicon via (TSV)).

A method of manufacturing a semiconductor device according to an embodiment includes: forming an insulating stacked structure by alternately stacking a plurality of interlayer insulating layers and a plurality of sacrificial insulating layers; forming a channel structure, a vertical through portion, and an opening for a separation structure that penetrate the insulating stacked structure; forming an electrode stacked structure by replacing the plurality of sacrificial insulating layers disposed in at least a portion of the insulating stacked structure with electrodes through the opening for the separation structure; forming a separation structure by filling the opening for the separation structure with a filling material; forming an expanded through portion extending in a horizontal direction by removing a portion of the plurality of interlayer insulating layers disposed around the vertical through portion through the vertical through portion; and forming a capacitor structure by sequentially forming a sidewall dielectric layer and a through electrode within a capacitor through portion that includes the vertical through portion and the expanded through portion.

The sidewall dielectric layer may have a dielectric constant higher than a dielectric constant of one of the plurality of interlayer insulating layers. For example, the sidewall dielectric layer may include a high dielectric constant material having a dielectric constant higher than a dielectric constant of silicon oxide, a ferroelectric material, an antiferroelectric material, or a combination thereof.

The sidewall dielectric layer may include a first dielectric portion disposed on a side surface of the vertical through portion, and a second dielectric portion in the expanded through portion and extending in the horizontal direction from the first dielectric portion.

The semiconductor device may further include a circuit region electrically connected to a cell region including the electrode stacked structure. The through electrode may be an input/output connection wiring connected to the circuit region.

While some examples have been described in connection with what is presently considered to be some practical embodiments, it is to be understood that the disclosure is not limited to the disclosed embodiments, and that the disclosure is intended to cover various modifications and equivalent arrangements included within the spirit and scope of the appended claims.

What is claimed is:

1. A semiconductor device, comprising:
an electrode stacked structure in a first region and a second region in a plan view, wherein the electrode stacked structure includes a first stacked structure, wherein the first stacked structure includes a plurality of electrodes and a plurality of interlayer insulating layers that are alternately stacked on each other;
a memory cell structure in the first region; and
a capacitor structure in the second region,
wherein the capacitor structure includes the plurality of electrodes, a through electrode penetrating the electrode stacked structure, and a sidewall dielectric layer disposed on a side surface of the through electrode,
wherein the sidewall dielectric layer includes a first dielectric portion and a second dielectric portion,
wherein the first dielectric portion is between at least one of the plurality of electrodes and the through electrode, and
wherein the second dielectric portion is between at least one of the plurality of interlayer insulating layers and the through electrode and extends in a horizontal direction from the first dielectric portion.

2. The semiconductor device of claim 1, wherein the plurality of electrodes include a plurality of gate electrodes,
wherein the memory cell structure includes a channel structure, and
wherein the channel structure penetrates the electrode stacked structure in the first region and includes a channel layer and a gate dielectric layer.

3. The semiconductor device of claim 1, further comprising:
a circuit region electrically connected to a cell region that includes the electrode stacked structure, the memory cell structure, and the capacitor structure,
wherein the through electrode is an input/output connection wiring connected to the circuit region.

4. The semiconductor device of claim 1, wherein the sidewall dielectric layer includes a plurality of first dielectric portions respectively disposed between the plurality of electrodes and the through electrode,
wherein the sidewall dielectric layer includes a plurality of second dielectric portions respectively disposed between the plurality of interlayer insulating layers and the through electrode,
wherein, in the first region, the electrode stacked structure has the first stacked structure, and
wherein, in at least a portion of the second region, the electrode stacked structure has a second stacked structure where the plurality of electrodes and the plurality of second dielectric portions are alternately stacked on each other.

5. The semiconductor device of claim 1, wherein the sidewall dielectric layer has a dielectric constant higher than a dielectric constant of one of the plurality of interlayer insulating layers, and
wherein the sidewall dielectric layer includes a high dielectric constant material having a dielectric constant higher than a dielectric constant of silicon oxide, a ferroelectric material, an antiferroelectric material, or a combination thereof.

6. The semiconductor device of claim 1, wherein the capacitor structure further includes a voltage application electrode that penetrates the electrode stacked structure in the second region to apply a voltage to the plurality of electrodes.

7. The semiconductor device of claim 6, wherein the second region includes a first capacitor region where the through electrode is disposed and a second capacitor region where the voltage application electrode is disposed, and
wherein the electrode stacked structure has different stacked structures in the first capacitor region and the second capacitor region, or the electrode stacked structure has the first stacked structure in the second capacitor region.

8. The semiconductor device of claim 6, wherein the capacitor structure includes a plurality of voltage application electrodes that penetrate the electrode stacked structure in the second region, and
wherein the plurality of voltage application electrodes include an individual voltage application electrode that is individually electrically connected to one of the plurality of electrodes.

9. The semiconductor device of claim 6, wherein the voltage application electrode includes a common voltage application electrode that is connected to the plurality of electrodes together.

10. The semiconductor device of claim 1, further comprising:
a regional separation portion that electrically separates electrodes of the plurality of electrodes in the first region and electrodes of the plurality of electrodes in the second region.

11. The semiconductor device of claim 10, wherein the regional separation portion includes an insulating stacked structure or an insulating separation structure disposed between the first region and the second region.

12. The semiconductor device of claim 1, wherein the capacitor structure includes a plurality of through electrodes that are spaced apart from each other in a plan view, and
wherein the capacitor structure includes a plurality of sidewall dielectric layers that are disposed on side surfaces of the plurality of through electrodes and are spaced apart from each other in a plan view.

13. The semiconductor device of claim 1, wherein the capacitor structure includes a plurality of through electrodes that are spaced apart from each other in a plan view, and
wherein the second dielectric portion of the sidewall dielectric layer disposed on a side surface of one of the plurality of through electrodes is connected to the second dielectric portion of the sidewall dielectric layer disposed on a side surface of another one of the plurality of through electrodes in a plan view.

14. The semiconductor device of claim 1, further comprising:
an interfacial layer disposed at least one of between the through electrode and the sidewall dielectric layer and between the sidewall dielectric layer and the electrode stacked structure.

15. The semiconductor device of claim 1, wherein the semiconductor device includes a memory region and an outer region outside the memory region in a plan view, and
wherein the capacitor structure is in the outer region.

16. A semiconductor device, comprising:
an electrode stacked structure including a first stacked region and a second stacked region, wherein the first stacked region has a first stacked structure including a plurality of electrodes and a plurality of interlayer insulating layers that are alternately stacked on each other, wherein the second stacked region has a second stacked structure including the plurality of electrodes and a plurality of dielectric portions that are alternately stacked on each other;
a memory cell structure in the first stacked region; and
a capacitor structure in a portion including the second stacked region,
wherein the plurality of dielectric portions have a dielectric constant higher than a dielectric constant of one of the plurality of interlayer insulating layers, and
wherein the capacitor structure includes the plurality of electrodes, a through electrode penetrating the electrode stacked structure, and a sidewall dielectric layer disposed on a side surface of the through electrode.

17. The semiconductor device of claim 16, wherein the plurality of dielectric portions are formed of a portion of the sidewall dielectric layer, or the plurality of dielectric portions and the sidewall dielectric layer include the same material.

18. The semiconductor device of claim 16, further comprising:
a circuit region electrically connected to a cell region that includes the electrode stacked structure, the memory cell structure, and the capacitor structure,
wherein the through electrode is an input/output connection wiring connected to the circuit region.

19. The semiconductor device of claim 16, wherein the capacitor structure further includes a voltage application electrode that penetrates the electrode stacked structure to apply a voltage to the plurality of electrodes.

20. An electronic system, comprising:
a main substrate;
a semiconductor device disposed on the main substrate; and
a controller electrically connected to the semiconductor device disposed on the main substrate,
wherein the semiconductor device comprises:
an electrode stacked structure in a first region and a second region in a plan view, wherein the electrode stacked structure includes a first stacked structure, wherein the first stacked structure includes a plurality of electrodes and a plurality of interlayer insulating layers that are alternately stacked on each other;
a memory cell structure in the first region; and
a capacitor structure in the second region,
wherein the capacitor structure includes the plurality of electrodes, a through electrode penetrating the electrode stacked structure, and a sidewall dielectric layer disposed on a side surface of the through electrode,
wherein the sidewall dielectric layer includes a first dielectric portion and a second dielectric portion,
wherein the first dielectric portion is between at least one of the plurality of electrodes and the through electrode, and
wherein the second dielectric portion is between at least one of the plurality of interlayer insulating layers and the through electrode and extends in a horizontal direction from the first dielectric portion.
